(19) United States
(12) Patent Application Publication
(10) Pub. No.: US 2024/0357841 A1
(43) Pub. Date: Oct. 24, 2024

(54) PERYLENE DIIMIDE CATHODE INTERLAYER FOR ORGANIC PHOTOVOLTAICS

(71) Applicant: UTI Limited Partnership, Calgary (CA)

(72) Inventors: Mahmoud Elsayed FARHAT, Calgary, Alberta (CA); Gregory C. WELCH, Calgary, Alberta (CA)

(21) Appl. No.: 18/683,908

(22) PCT Filed: Aug. 20, 2022
(86) PCT No.: PCT/IB2022/057824

§ 371 Date: Feb. 15, 2024

Related U.S. Application Data
(60) Provisional application No. 63/235,452, filed on Aug. 20, 2021.

(51) Int. Cl. H10K 30/50; H10K 30/81; H10K 30/85; H10K 30/86; H10K 71/13; H10K 85/60; H10K 102/20

(52) U.S. Cl. CPC H10K 30/50; H10K 30/81; H10K 30/85; H10K 30/86; H10K 71/135; H10K 85/621; H10K 2102/20

(57) ABSTRACT

Multilayer organic electronic devices having an electron transport layer (ETL). The ETL is a film comprising an N-annulated perylene diimide (NPDI) compound having at least one pyrrole N—H bond and at least 1 equivalent of Cs₂CO₃ with respect to the NPDI compound and the number of pyrrolic N—H bonds in the NPDI compound. The ETL is positioned between the photoactive layer and the top electrode (cathode). Multilayer devices including the ETL are fabricated employing immiscible solvent methods. A method for making the ETL layers is provided which employs an ink formulation in which the NPDI compound is solubilized in a selected polar solvent by addition of at least one equivalent of Cs₂CO₃ respect to the NPDI compound. Exemplary polar solvents include ethanol, 1-propanol, ethyl acetate and mixtures thereof.

### CROSS-REFERENCE TO RELATED APPLICATIONS

This application claims the benefit of U.S. provisional application 63/235,452, filed Aug. 20, 2021 which is incorporated by reference herein in its entirety.

### BACKGROUND

The invention relates to alcohol and related formulations that can be printed or coated to form organic films that are electronically active and solvent resistant. The films are relevant to the field of organic electronics with potential use in solar cells, light emitting diodes, sensors, transistors, electrochromics, thermoelectrics, photocatalysis (photoanodes and photocathodes).

Multiple research groups have reported record high power conversion efficiencies (PCEs)>18% for single junction organic photovoltaics (OPVs). [Li et al., Nat. Energy 2021; Lin et al., ACS Energy Lett. 2020, 5, 9, 2935-2944.] The rapid improvement in PCEs can largely be attributed to the development of new materials used as solar light harvesters and interlayers.

Solution-processable OPV devices are composed of stacked multilayers in which the photoactive materials (e.g., bulk heterojunction materials) are sandwiched between electrodes and functional interlayers. FIGS. 1A and 1B show the two device architectures commonly used in OPV device fabrication; conventional (FIG. 1A) or inverted (FIG. 1B) configurations. The conventional devices have the architecture: glass/bottom conductive electrode (2)/hole transport layer (HTL, 4)/photoactive layer (5, bulk heterojunction; BHJ)/electron transport layer (6, ETL)/top metal electrode (8, e.g., silver (Ag), copper (Cu) etc.). The inverted configuration devices have the architecture: glass/bottom conductive electrode (2)/ETL (6)/photoactive layer (5)/HTL (4)/top metal electrode (8).

In solution-processable OPVs, different layers are deposited using solvents immiscible with the underlying layer to avoid ruining or dissolving this under layer. Usually, the interlayers (ETL and HTL) are processed from water or alcohols, while the photoactive layers are processed from organic non-polar solvents. Interlayers play a critical role in the device efficiency and long-term stability. [Nian et al., J. Am. Chem. Soc. 2015, 137, 6995; Page et al., Science 2014, 346, 441; Yao et al., Nat. Commun. 2020, 11, 2726; Sorrentino et al., Energy Environ. Sci. 2021, 14, 180.]

With device PCEs already higher than 15%, the upscaling of OPV devices to functional modules has become a focus. Several photoactive materials, as well as HTL materials, have been successfully coated using scalable techniques for efficient large-area OPVs. [Farahat, et al., ACS Appl. Mater. Interfaces 2020, 12, 43684; An et al., Energy Environ. Sci. 2021, 14, 3438-3446; Strohm et al., Energy Environ. Sci. 2018, 11, 2225; Kang et al., Adv. Mater. 2018, 30, 1801718; Sun et al., Joule 2020, 4, 407.]

In contrast, few ETL materials have been successfully coated for large area OPVs and in general for other electronic devices, such as org organic light-emitting diodes (OLEDs), methods to process ETL materials into large area functional films is ongoing. [Dubey et al. Adv. Material Technology 2021, 2100264] Tin oxide (SnO₂) and zinc oxide (ZnO) are inorganic ETLs that have been successfully employed in large-area OPVs. [Bai et al., Sci. China Chem. 2020, 63, 957; Lin et al., Adv. Energy Mater. 2018, 8, 1701942.]

The chemical structures of exemplary organic ETLs are shown in Scheme 1, below. NDI-N and PNDIT-F3N-Br both proved to be printable. [Sun et al., Joule 2020, 4, 40; Kan et al., Joule 2019, 3, 227.] However, the scarcity of roll-to-roll (R2R) compatible ETLs has greatly impeded the pace towards OPV commercialization. There is an urgent need for new printable ETLs with high electron mobilities and thickness tolerance. Because of their excellent thermal and photochemical stability, high electron affinities, and facile synthesis, perylene diimides (PDI) are an attractive class of materials for organic electronics. [Huang et al., J. Org. Chem. 2011, 76, 2386.] The chemical structure of some examples of perylene diimides (PDIN, PDINO, PDINN, PDIN-Hex and PDIN-H) useful for ETLs are shown in Scheme 2.

Zhang et al. reported the first two successful PDI-based electron transport layers (ETL). PDIs functionalized with amino (PDIN) or amino-N-oxide (PDINO) groups at the imidic position to enable processing into films from solvents immiscible with the photoactive layer (e.g. alcohol) and are efficient cathode interlayers for low work function (WF) electrodes (e.g., Al). [Zhang et al., Wang, Energy Environ. Sci. 2014, 7, 1966.] A follow up study reported a further modified PDI functionalized with an aliphatic amine (PDINN). [Yao et al., Nat. Commun. 2020, 11, 2726.]

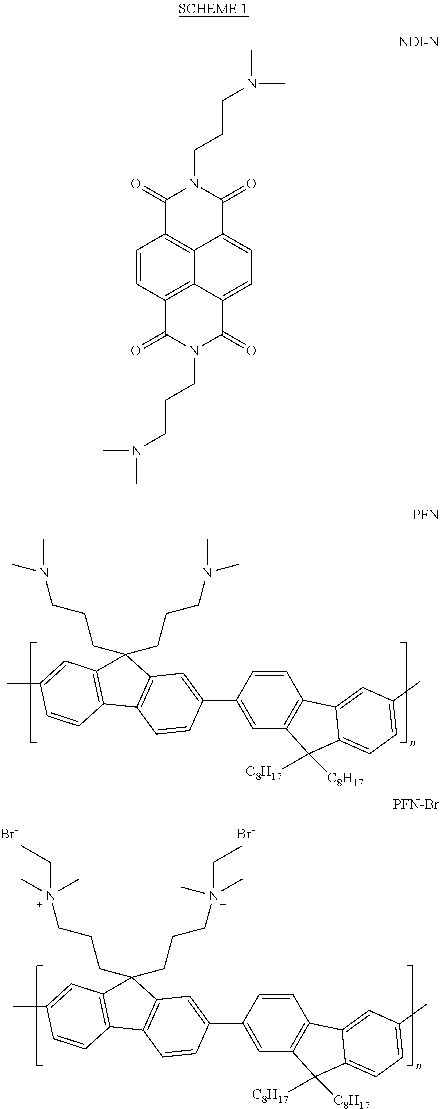

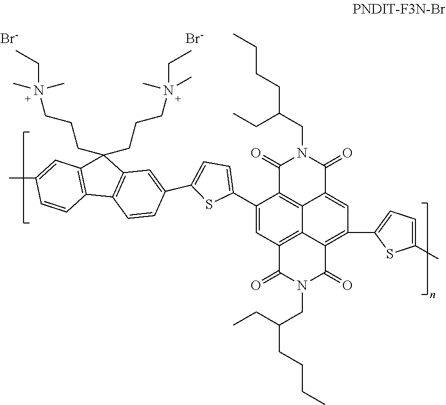

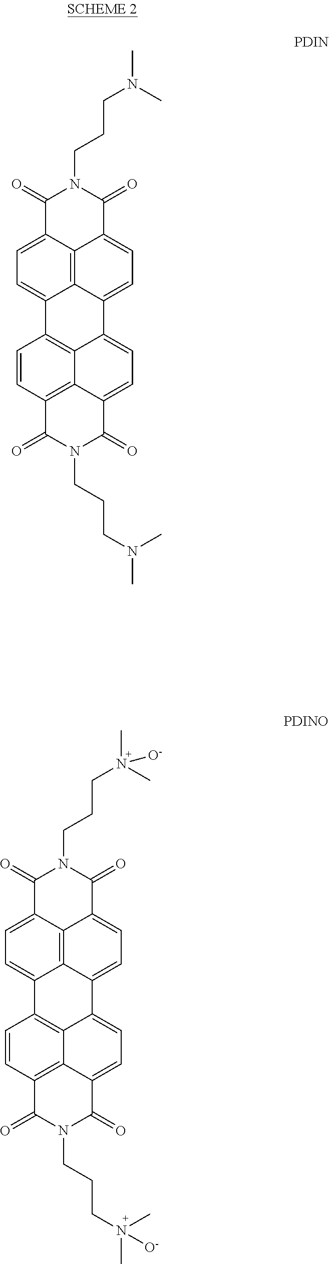

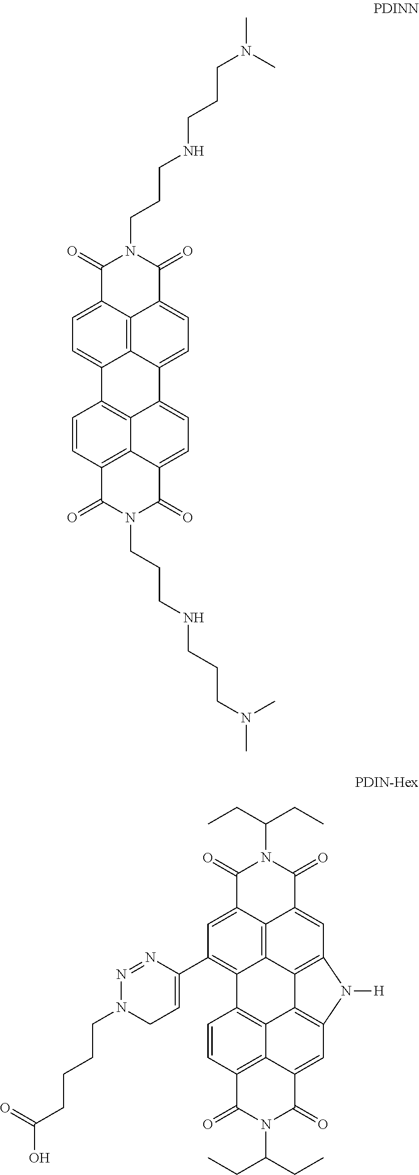 [SMILES: CN(C)CCCNCCCN1C(=O)c2ccc3c4ccc5c6c(ccc(c7ccc(c2c37)C1=O)c64)C(=O)N(CCCNCCCN(C)C)C5=O ; CCC(CC)n1c(=O)c2ccc3c4c(C5=CCN(CCCCC(=O)O)N=N5)cc5c(=O)n(C(CC)CC)c(=O)c6cc7[nH]c8cc(c1=O)c2c3c8c7c4c56]

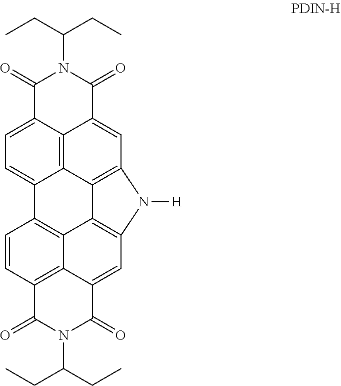 [SMILES: CCC(CC)n1c(=O)c2ccc3c4ccc5c(=O)n(C(CC)CC)c(=O)c6cc7[nH]c8cc(c1=O)c2c3c8c7c4c56]

The main difference between the PDIN and PDINO and PDINN, is the ability of PDINN to reduce the high WF (Work Function) values of electrodes, such as Ag and Cu. A general requirement for efficient PDI-based ETL (in either the inverted or conventional OPV structure) is the ability to form an ohmic contact (tune energy levels) at the electrode/active layer interface to avoid Schottky barrier formation. [Yao et al., Nat.

Commun. 2020, 11, 2726 For ETLs used in inverted device structure, the ETL should be organic solvent resistant (e.g., resistant to chlorinated and/or aromatic organic solvents) to allow for photoactive layer deposition on top of the ETL. For ETLs used in conventional device structure where the ETL is layered on top of the photoactive layer, the ETL should be processable from solvents which are immiscible, yet have good wettability, with the active layer, and they should have the ability to tune the high WF top contact electrode (e.g., Ag and Cu). [Yao et al., Nat. Commun. 2020, 11, 2726.]

N-annulated PDIs have been reported for use as ETLs in OPVs. [Abd-Ellah et al., ACS Appl. Electron. Mater. 2019, 1, 1590; Sadeghianlemraski et al., ACS Appl. Energy Mater. 2020, 3, 11655.] Functionalizing the PDI pyrrolic N-position with a carboxylic acid allowed for attachment to ZnO and boosted PCE of inverted type devices. [Abd-Ellah et al., ACS Appl. Electron. Mater. 2019, 1, 1590.]A PDI with a pyrrolic N—H bond (e.g., PDIN-H, Scheme 2) could be rendered alcohol or water soluble upon deprotonation by base (e.g., NaOH) and printed on top of ZnO leading to inverted type OPVs with enhanced photostability. [Sadeghianlemraski et al., ACS Appl. Energy Mater. 2020, 3, 11655; Harding et al., Mater. Horiz. 2020, 7, 2959.]

To enable the dissolution of PDIN-H in alcohols (e.g., 1-propanol; PrOH), the addition of the base NaOH was required. The base is believed to deprotonate PDIN-H leading to the formation of an alcohol soluble ion pair. Upon film formation the PDIN⁻ anion is spontaneously re-protonated yielding a uniform film of PDIN-H. In addition to having a low work function (ca. −3.9 eV), the films formed are solvent resistant owing to the presence of strong intermolecular NH . . . O bonds rendering the material insoluble after drying. A clear limitation of such ETLs was the use of NaOH, a caustic base, and a low electron mobility requiring the paring with ZnO. This work is additionally described and extended in U.S. Provisional application 63/019,012, filed May 1, 2020 and PCT application PCT/CA2021/050603, filed Apr. 30, 2021, each of which are incorporated by reference herein in its entirety.

The present disclosure at least in part, describes the use of cesium carbonate (Cs₂CO₃) in film precursor formulations as a base for the formation of ETLs employing PDIN-H and derivatives thereof. This disclosure further describes the use of such ETLs in conventional OPV device configurations where the ETL is formed on and in contact with a photoactive layer as a neat film without an additional electron transport material (e.g. without ZnO). The use of Cs₂CO₃ in the film precursor formulations (also called inks herein) enables printability and enhances ETL performance.

The base, Cs₂CO₃, was previously reported as a solution-processed ETL for organic electronics. [Huang et al., Adv. Funct. Mater. 2007, 17, 1966; Huang et al., Adv. Mater. 2008, 20, 415; Liao et al., Appl. Phys. Lett. 2008, 92, 173303.] Compared to other carbonates, Cs₂CO₃ (CC) is the only one soluble in alcohols (e.g., 1-propanol). With its low-cost, Cs₂CO₃ is attractive for use with PDIN-H as a deprotonating base and a possible n-dopant.

For improved device economics, roll-to-roll coating of conventional OPV architectures in air are much preferred. Conventional OPVs require low work function, electron harvesting interlayers as the top interface (also called cathode interlayers). Traditional materials based on metal oxides are often not compatible with coating in air and/or the use of green solvents due to detrimental interaction with underlying layers of the OPV. With respect to device manufacture and performance, the disclosure provides for processing conditions for film formation and device manufacture that do not require stringent control. Previously reported high-performance OPV devices were fabricated and tested under inert atmosphere (dry nitrogen or argon) inside a glovebox with extremely low levels of water and oxygen<10 ppm. [Li et al., Nat. Energy 2021, 1; Lin et al., ACS Energy Lett. 2020, 5, 9, 2935-2964.] For example, the PM6:Y6 BHJ system is reported to reach PCEs>15% using fabrication under such stringent conditions. [Guo et al., Mater. Chem. Front. 2021, 5, 3257.] In contrast, the present disclosure allows the use of industry compatible and commercially viable fabrication techniques.

Devices exemplified herein can be fabricated in air at room temperature and without any humidity control precautions. Recently, An et al. reported using machine learning for slot-die coating PM6:Y6 in air and the highest PCE reported for this system on glass substrates was only 9.7% under hot coating conditions (90° C. at slot-die head and 130° C. at the bed). [An et al., Energy Environ. Sci. 2021, 14, 3438-3446.] The results of An et al. indicate that processing in air compared to processing in inert atmosphere with humidity and oxygen control can have a significant detrimental effect on device performance. The methods and materials herein demonstrate that good device performance can be obtained with the use of ETL and cathode interlayers as described herein, even when processing conditions are not stringently controlled.

### SUMMARY

The invention provides multilayer organic electronic devices comprising an electron transport layer (ETL). The disclosure more specifically provides such multilayer devices fabricated employing immiscible solvent methods to form one or more layers of the multilayer device. Such devices include those having a photoactive layer and particularly a photoactive layer in contact with the ETL. In embodiments, the ETL is a cathode interlayer.

In embodiments, the invention provides a multi-layer Organic Photovoltaic (OPV) device comprising a top electrode, a bottom electrode, a photoactive layer and an electron transport layer (ETL) between the top and bottom electrodes, wherein the ETL is a film comprising an N-annulated perylene diimide (NPDI) compound having at least one pyrrole N—H bond and at least 1 equivalent of Cs₂CO₃ with respect to the at least one pyrrole N—H bond of the NPDI compound.

In embodiments, the multilayer device, particularly the OPV device, has conventional geometry wherein at least one ETL is positioned between the photoactive layer and the top electrode (cathode), thus providing a cathode interlayer. In embodiments, the multilayer device, particularly the OPV device, further comprises a hole transport layer (HTL). In embodiments, the HTL is positioned between the photoactive layer and the bottom electrode.

In embodiments, the photoactive layer is a bulk heterojunction layer. In embodiments, the top electrode comprises metal. In embodiments, the top electrode is a metal electrode. In embodiments, the top electrode comprises Ag, Cu, Au or Al or mixtures or alloys thereof. In embodiments, the top electrode is Ag, Cu, Au or AI or mixtures or alloys thereof. In embodiments, the bottom electrode is glass/ITO, glass/reduced graphene oxide or glass/high conductivity PEDOT:PSS. In a specific embodiment, the top electrode comprises or is Ag, Au or Cu and the bottom electrode comprises or is glass/ITO. In a specific embodiment, the top electrode comprises or is Ag and the bottom electrode is glass/ITO. In a specific embodiment, the top electrode comprises or is Cu and the bottom electrode is glass/ITO.

In embodiments, the ETL is processed and formed in the multilayer device in air. In embodiments, the ETL is processed and formed in the multilayer device in air without humidity control. In embodiments, the ETL is processed (e.g., the film precursor formulation (ink) is prepared) in air without humidity control. In embodiments, the multilayer device is fabricated in air without humidity control, except that one or both electrodes may be formed by vacuum deposition. In embodiments, the OPV device is fabricated in air without humidity control, except that one or both electrodes may be formed by vacuum deposition. In embodiments, the multilayer device is tested in air without humidity control. In embodiments, the OPV device is tested in air without humidity control. In embodiments, the multilayer device is processed and tested in air with oxygen levels greater than 10 ppm. In embodiments, the multilayer device is processed and tested with humidity greater than 10 ppm. In embodiments, the multilayer device is processed and tested in air with oxygen levels greater than 10 ppm and humidity greater than 10 ppm.

In embodiments, the NPDI compound is a compound of Formula I:

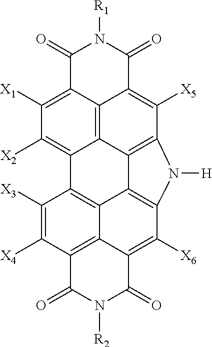

wherein:
R₁ and R₂ are independently a substituted or unsubstituted C₁ to C₁₈ linear or branched alkyl; and
X₁-X₆ are independently selected from H, a C₁-C₆ substituted or unsubstituted alkyl, a halogen, NO₂, or CN or X₂ and X₃ together form —S—S— and X₁, X₄, X₅ and X₆ are independently selected from H, a C₁-C₆ substituted or unsubstituted alkyl, a halogen, NO₂, or CN;
wherein optional substitution of alkyl groups is substitution with one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl, —NHR′ or —NR′R″, wherein R′ and R″ are independently H, an unsubstituted C₁ to C₆ alkyl or a C₁-C₃ halogen-substituted C₁-C₆ alkyl.

In an embodiment, the NPDI compound is a compound of Formula I, wherein X₁-X₆ are all hydrogens and R₁ and R₂ are independently branched alkyl groups having 5-11 carbon atoms. In an embodiment, the NPDI compound is compound 1.

In an embodiment, the NPDI compound is a compound of Formula I, wherein one or two of X₁-X₆ are —CN, the remaining X₁-X₆ are hydrogens and R₁ and R₂ are independently branched alkyl groups having 5-11 carbon atoms. In an embodiment, the NPDI compound is a compound of Formula I, wherein one or two of X₁, X₂, X₅ and X₆ are —CN and the remaining X₁-X₆ are hydrogens and R₁ and R₂ are independently branched alkyl groups having 5-11 carbon atoms. In an embodiment, the NPDI compound is a compound of Formula I, wherein X₁, and X₆ are —CN and the remaining X₁-X₆ are hydrogens and R₁ and R₂ are independently branched alkyl groups having 5-11 carbon atoms. In an embodiment, the NPDI compound is compound 1. In an embodiment, the NPDI compound is compound 2. In an embodiment, the NPDI compound is compound 3.

In embodiments, the ETL ranges in thickness from 1 to 100 nm. In embodiments, the ETL ranges from 5-50 nm in thickness. In embodiments, the ETL ranges from 10 to 50 nm in thickness. In embodiments, the ETL ranges from 20 to 40 nm in thickness.

In embodiments, the ETL contains from 1-10 equivalents of Cs₂CO₃ with respect to the NPDI compound and number of pyrrolic N—H bonds therein in the ETL. In embodiments, the ETL contains from 1-5 equivalents of Cs₂CO₃ with respect to the NPDI compound and number of pyrrolic N—H bonds therein in the ETL. In embodiments, the ETL contains from 1-3 equivalents of Cs₂CO₃ with respect to the with respect to the NPDI compound and number of pyrrolic N—H bonds therein in the ETL. In embodiments, the ETL contains from 2-3 equivalents of Cs₂CO₃ with respect to the NPDI compound and number of pyrrolic N—H bonds therein in the ETL. When the NPDI compound has one pyrrolic N—H bond, the number of equivalents of Cs₂CO₃ in the ETL is with respect to the moles of the NPDI compound in the ETL.

In embodiments, the ETL of the multilayer device is formed by:
(a) deposition of a solution comprising the N-annulated perylene diimide (NPDI) compound having at least one pyrrole N—H bond and at least 1 equivalent of Cs₂CO₃ with respect to the NPDI compound and number of pyrrole N—H bonds in the NPDI compound in the solution; and (b) removal of the solvent to form the ETL.

In embodiments, the solvent of the solution is a polar solvent. In embodiments, the solvent is an aprotic polar solvent. In embodiments, the solvent of the solution is a polar solvent in which the NPDI compound on addition of the at least 1 equivalent of Cs₂CO₃ is soluble. In embodiments, the solvent of the solution is a polar solvent in which the NPDI compound on addition of the at least 1 equivalent of Cs₂CO₃ is soluble at room temperature at a level greater than 0.1 g/100 mL solvent. In embodiments, the solvent of the solution is a polar solvent in which the NPDI compound on addition of the at least 1 equivalent of Cs₂CO₃ is soluble at room temperature at a level equal to or greater than 0.5 g/100 mL solvent. In embodiments, the solvent of the solution is a polar solvent in which the NPDI compound on addition of the at least 1 equivalent of Cs₂CO₃ is soluble at a level equal to or greater than 1.0 g/100 mL solvent.

In embodiments, the polar solvent is an aqueous solution, an alkyl alcohol or any miscible mixtures thereof. In embodiments, the polar solvent is an aqueous solution, a C1-C6 alcohol or any miscible mixtures thereof. In embodiments, the polar solvent is water or a C2-C4 alcohol or any mixtures thereof. In embodiments, the polar solvent is a C2-C4 alcohol or any mixtures thereof. In embodiments, the polar solvent is 1-propanol. In embodiments, the polar solvent is ethanol. In embodiments, the polar solvent is a mixture of 1-propanol with a C2-C4 alcohol, other than 1-propanol. In embodiments, the polar solvent is a mixture of 1-propanol and ethanol. In embodiments, the polar solvent is a mixture of 1-propanol and 2-propanol. In embodiments, the concentration of the NPDI compound in the polar solvent ranges from 0.1 to 100 mg/mL. In embodiments, the concentration of the NPDI compound in the polar solvent ranges from 0.5 to 50 mg/mL.

In embodiments, the solvent is an alkyl ester having 2 to 6 carbon atoms. In embodiments, the solvent is an alkyl ester having 2 to 6 carbon atoms (a C2-C6 ester) containing a sufficient amount of an alkyl alcohol, particularly a C2-C4 alcohol, to solubilize the amount of Cs₂CO₃ to be added. In an embodiment, the alkyl ester is ethyl acetate and the alcohol is ethanol or 1-propanol. In an embodiment, the amount of alkyl ester in the solvent ranges from 60% to 100% by volume. In an embodiment, the amount of alkyl ester in the solvent ranges from 60% to 100% by volume. In an embodiment, the amount of alkyl ester in the solvent ranges from 60% to 99.9% by volume. In an embodiment, the amount of alkyl ester in the solvent ranges from 90% to 99.9% by volume. In an embodiment, the amount of alkyl ester in the solvent ranges from 90% to 99.5% by volume. In an embodiment, the amount of alkyl ester in the solvent ranges from 90% to 99% by volume. In an embodiment, the amount of alkyl ester in the solvent ranges from 90% to 95% by volume. In an embodiment, the volume ratio of alkyl ester to alkyl alcohol in the solvent ranges from 20:1 to 15:1. In an embodiment, the volume ratio of alkyl ester to alkyl alcohol in the solvent ranges from 18:1 to 16:1. In an embodiment, the volume ratio of ethyl acetate to ethanol or 1-propanol in the solvent ranges from 20:1 to 15:1. In an embodiment, the volume ratio of ethyl acetate to 1-propanol or ethanol in the solvent ranges from 18:1 to 16:1.

In embodiments, the solution for forming the ETL is deposited by spin coating, spray coating, ink-jet printing, screen printing or slot die coating. In embodiments, the solution for forming the ETL is deposited by spin coating or slot die coating. In embodiments, the solution for forming the ETL is deposited and solvent is removed in air without humidity control.

The invention also provides a method for fabricating a multilayer device as described herein and particularly a OPV device, which comprises (a) deposition of a solution comprising the N-annulated perylene diimide (NPDI) compound having at least one pyrrole N—H bond and at least 1 equivalent of Cs₂CO₃ with respect to the N-annulated perylene diimide (NPDI) compound and the number of pyrrole N—H bond therein in the solvent; and
(b) removal of the solvent to form the ETLs.

In embodiments, the concentration of the NPDI compound in the solvent ranges from 0.1 to 100 mg/mL. In embodiments, the concentration of the NPDI compound in the solvent ranges from 0.5 to 50 mg/mL. In embodiments, the concentration of the NPDI compound in the solvent ranges from 0.1 to 10 mg/mL. In embodiments, the concentration of the NPDI compound in the solvent ranges from 0.1 to 5 mg/mL. In embodiments, the concentration of the NPDI compound in the solvent ranges from 0.1 to 7.5 mg/mL. In embodiments, the concentration of the NPDI compound in the solvent ranges from 0.1 to 1 mg/mL. In embodiments, the concentration of the NPDI compound in the solvent ranges from 0.1 to 0.75 mg/mL. In embodiments, the concentration of the NPDI compound in the solvent ranges from 0.2 to 0.6 mg/mL.

In embodiments, solvent removal is optionally facilitated by application of vacuum (reduced pressure) and heat. In embodiments, heating to remove solvent is limited to 100° C. or less. In embodiments, heating to remove solvent is limited to 80° C. or less.

In embodiments, heating to remove solvent is limited to 50° C. or less.

In embodiments, the solvent is a polar solvent. In embodiments, the polar solvent is an aqueous solution, an alkyl alcohol or any miscible mixtures thereof. In embodiments, the polar solvent is an aqueous solution, a C1-C6 alcohol or any miscible mixtures thereof. In embodiments, the polar solvent is water or a C2-C4 alcohol or any mixtures thereof. In embodiments, the polar solvent is a C2-C4 alcohol or any mixtures thereof.

In embodiments, the polar solvent is 1-propanol. In embodiments, the polar solvent is ethanol. In embodiments, the polar solvent is a mixture of 1-propanol with a C2-C4 alcohol, other than 1-propanol. In embodiments, the polar solvent is a mixture of 1-propanol and ethanol. In embodiments, the polar solvent is a mixture of 1-propanol and 2-propanol. In embodiments, the concentration of the NPDI compound in the polar solvent ranges from 0.1 to 100 mg/mL. In embodiments, the concentration of the NPDI compound in the polar solvent ranges from 0.5 to 50 mg/mL. In embodiments, the concentration of the NPDI compound in the polar solvent ranges from 0.1 to 10 mg/mL. In embodiments, the concentration of the NPDI compound in the polar solvent ranges from 0.1 to 5 mg/mL. In embodiments, the concentration of the NPDI compound in the polar solvent ranges from 0.1 to 7.5 mg/mL. In embodiments, the concentration of the NPDI compound in the polar solvent ranges from 0.1 to 1 mg/mL. In embodiments, the concentration of the NPDI compound in the polar solvent ranges from 0.1 to 0.75 mg/mL. In embodiments, the concentration of the NPDI compound in the polar solvent ranges from 0.2 to 0.6 mg/mL.

In embodiments, the solvent is a mixture of an aprotic polar solvent in which Cs₂CO₃ is at most slightly soluble and a polar solvent in which Cs₂CO₃ is at least soluble. In embodiments the aprotic polar solvent is present in the mixture at 60% or more by volume. In embodiments the aprotic polar solvent is present in the mixture at 80% or more by volume. In embodiments the aprotic polar solvent is present in the mixture at 90% or more by volume. In embodiments the aprotic polar solvent is present in the mixture at 99% or more by volume. In embodiments, the aprotic polar solvent is an alkyl ester or an alkyl ketone and the polar solvent is an alkyl alcohol. In embodiments, the aprotic polar solvent is an alkyl ester and the polar solvent is an alkyl alcohol. In embodiments, the aprotic polar solvent is ethyl acetate or acetone and the polar solvent is 1-propanol or ethanol. In embodiments, the aprotic polar solvent is ethyl acetate and the polar solvent is 1-propanol or ethanol. In embodiments, the aprotic polar solvent is ethyl acetate and the polar solvent is 1-propanol.

In embodiments of the method herein for making an ETL (interlayer or cathode interlayer), the solution containing the NPDI compound and Cs₂CO₃, particularly the solution in polar solvent, is deposited by spin coating, spray coating, ink-jet printing, screen printing or slot die coating. In embodiments, the ETL film is made in an OPV device.

In embodiments, the method herein for making an ETL (interlayer or cathode interlayer) is practiced in air without humidity control. In embodiments, the method herein for making an ETL (interlayer or cathode interlayer) is practiced in air with oxygen levels greater than 10 ppm. In embodiments, the method is practiced with humidity greater than 10 ppm. In embodiments, the method is practiced in air with oxygen levels greater than 10 ppm and humidity greater than 10 ppm. In embodiments, the ETL film is made in an OPV device.

In embodiments, the method herein for making an ETL (interlayer or cathode interlayer) is practiced using an NDPI compound of Formula I. In embodiments, the method is practiced with any one of compounds 1, 2 or 3. In embodiments, the ETL is formed by deposition of the solution on a photoactive layer. In embodiments, the ETL is formed by deposition of the solution on a bulk heterojunction layer.

In embodiments, the methods herein are employed to make OPV devices with ETL in conventional architecture. More specifically, the methods are employed to make such OPV devices employing bulk heterojunctions. Yet more specifically, the methods are employed to make such OPV devices employing PM6:Y6 or PBDB-T:PC₆₁BM as bulk heterojunctions. In embodiments, the methods herein are employed to make OPV devices with ETL in inverted architecture. More specifically, the methods are employed to make such inverted OPV devices employing bulk heterojunctions. Yet more specifically, the methods are employed to make such inverted OPV devices employing PM6:Y6 or PBDB-T:PC₆₁EM as bulk heterojunctions.

Other aspects, and embodiments of the disclosure will be apparent to one of ordinary skill in the art on consideration of the detailed description, drawings and non-limiting examples provided herewith.

### BRIEF DESCRIPTION OF THE DRAWINGS

FIGS. 1A and 1B schematically illustrate exemplary OPV device architectures. FIG. 1A illustrates a conventional (normal or non-inverted) configuration. FIG. 1B illustrates an inverted device configuration. The conventional devices have the architecture: glass/bottom conductive electrode (2)/hole transport layer (HTL, 4)/photoactive layer (5, bulk heterojunction; BHJ)/electron transport layer (6, ETL)/top metal electrode (8, e.g., silver (Ag), copper (Cu) etc.). The inverted configuration devices have the architecture: glass/bottom conductive electrode (2)/ETL (6)/photoactive layer (5)/HTL (4)/top metal electrode (8).

FIGS. 2A-2B illustrate deprotonation of the N-annulated PDI, solubilization and film formation. FIG. 2A shows the chemical structure of PDIN-H and the deprotonation product on addition of a molar excess of Cs₂CO₃ (CC). Treatment of a 10 mg/mL slurry of PDIN-H in 1-propanol (PrOH) (yellow/orange) with increasing equivalents of Cs₂CO₃ produces a purple ionic solution. Spin coating of the solution onto a support (e.g., polyethylene terephthalate (PET)) followed by drying to remove solvent results in a solvent-resistant red colored film. FIG. 2B shows the chemical structure of CN-PDIN-H and the deprotonation product on addition of a molar excess of Cs₂CO₃ (CC). Treatment of a 10 mg/mL slurry of CN-PDIN-H in 1-propanol (PrOH) (orange) with increasing equivalents of Cs₂CO₃ produces a deep purple ionic solution. Spin coating of the solution onto a support (e.g., polyethylene terephthalate (PET)) followed by drying to remove solvent results in a solvent-resistant red colored film.

FIGS. 3A and 3B illustrate optical absorption spectra of PDIN-H and CN-PDIN-H film spin coated on PET substrates. FIG. 3A shows the optical absorption spectra of (1) a PDIN-H film spin coated from a THF solution containing 10 mg/mL of PDIN-H (compound 1) compared to (2) a PDIN-H film spin coated on PET from a PrOH solution containing 10 mg/mL PDIN-H and 2 molar equivalents of CC with respect to PDIN-H. FIG. 3B shows the optical absorption spectra of (1) a CN-PDIN-H film spin coated on PET from a THF solution containing 10 mg/mL of PDIN-H (compound 1) compared to (2) a CN-PDIN-H film spin coated from a PrOH solution containing 10 mg/mL PDIN-H and 2 molar equivalents of CC with respect to PDIN-H.

FIG. 4 is a graph comparing optical absorption spectra of 0.05 mg/mL solutions of PDIN-H in PrOH with increasing molar equivalents of CC with respect to PDIN-H (ranging from 0 to 10 eq of CC). The color of the solutions change from yellow/orange to purple and the CC equivalents increase. Spectra are labeled in the graph with the number of eq of CC added.

FIGS. 5A-5D are J-V curves of a series of conventional OPV devices based on air processed PM6:Y6 BHJ (FIGS. 5A-C) or PBDB-T:PC₆₁BM (FIG. 5D) active layers fabricated with different ETL conditions for comparison. FIG. 5A shows curves for the OPV devices where various spin speeds were used to prepare the PDIN-H/Cs₂CO₃ ELT. Curve (1) is for the OPV without an ETL, (2) is for the OPV with an ETL film containing 2 eq of CC only, (3)-(6) are curves for the OPV where the ETL is formed by spin coating from a PrOH solution containing 0.5 mg/mL PDIN-h and 2 eq of CC at varying spin speeds (3K to 6 K, respectively). Curves 5 and 6 largely overlap. FIG. 5B shows curves for the OPV devices where various PDIN-H concentrations were used in PrOH with 2 eq of CC. Curve (1) is PrOH only, (2) is with 2 eq. CC only, (3) is with PDIN-H concentration of 0.5 mg/mL, (4) is with PDIN-H concentration of 1.0 mg/mL and (5) is with PDIN-H concentration 1.5 mg/mL. Curves 4 and 5 largely overlap. FIG. 5C shows curves for the OPV devices where PDIn-H concentration is 0.5 mg/mL and where various Cs₂CO₃ molar equivalents are used in PDIN-H/Cs₂CO₃ PrOH solution. Curve (1) is PrOH only, (2) is for CC only, (3) is with 1 eq of CC, (4) is with 2 eq of CC and (5) is with 3 eq of CC. FIG. 5D shows curves for air processed OPV devices with PBDB-T:PC₆₁BM active layers with spin coated PDIN-H/Cs₂CO₃ (0.5 mg/mL PDIN-H/2 eq CC) in PrOH at two different spin speeds (4K and 6K). Curve (1) is Ag only, no ETL, (2) is PrOH only, (3) is CC only, (4) is PDIN-H/Cs₂CO₃ (0.5 mg/mL PDIN-H/2 eq CC) in PrOH at spin speed 4K and (5) is the same PrOH solution coated at spin speed 6K. See details in Example 1 and Table 1.

FIG. 6 illustrates J-V curves of conventional OPV devices with PBDB-T:PC₆₁BM active layers with spin coated ETL layers with PDIN-H/Cs₂CO₃ with various Cs₂CO₃ molar equivalents. The ETL are spin coated from PrOH solutions containing 0.5 mg/mL of PDIN-H. Curve (1) is a control with no ETL layer, (2) is spun from solution with 2 eq of CC, (3) is spun from solution with 3 eq of CC, (4) is spun from solution with 4 eq of CC, and (5) is spun from solution with 5 eq of CC. In this figure curves (1) and (2) largely overlap.

FIG. 7 shows J-V curves of conventional OPV devices with PBDB-T:PC₆₁BM active layers with spin coated PDIN-H/Cs₂CO₃ from solutions in ethanol (EtOH) and 1-propanol (PrOH). The ETL are spin coated from solutions containing 0.5 mg/mL of PDIN-H and 1 or 2 eq of CC. Curve (1) is no ETL (Ag only), (2) is EtOH only, (3) shows curve for a device with ETL layer spun from a solution of PDIN-H in EtOH with 1 eq of CC, (4) shows curve for a device with ETL layer spun from a solution of PDIN-H in ETOH with 2 eq of CC, and (5) shows curve for a device with ETL layer spun from a solution of PDIN-H in PrOH with 2 eq of CC. Curves 1 and 2 overlap at higher voltage bias.

FIG. 8 shows J-V curves of conventional OPV devices with PBDB-T:PC₆₁BM active layers with spin coated ETL layers from PDIN-H/Cs₂CO₃ solutions in alcohol mixture. Curve (1) is a device with no ETI layer (only Ag), (2) is a device with an ETL layer spun from a PrOH (1-propanol) solution of 0.5 mg/mL PDIN-H with 2 eq of CC, (3) is a device with an ETL layer spun from an analogous solution in a PrOH:EtOH (3:1 v:v) mixture, (4) is a device with ETL layer spun from an analogous solution in a PrOH:EtOH (1:1 v:v) mixture, (5) is a device with ETL layer spun from an analogous solution in a PrOH:IPA (iso-propyl alcohol) (3:1 v:v) mixture, and (6) is a device with ETL layer spun from an analogous solution in a PrOH:IPA (iso-propyl alcohol) (1:1 v:v) mixture. Curves 4, 5 and 6 largely overlap.

FIGS. 9A and 9B compare J-V curves of conventional OPV devices with PM6:Y6 active layers with slot-die coated PDIN-H/CC interlayers (FIG. 9A) and spin coated PDIN-H/CC interlayers (FIG. 9B) from EA:PrOH (1.0:0.06 v:v). FIG. 9A shows the J-V curves for PM6:Y6 devices with (1) PDIN-H/CC layers or (2) CN-PDIN-H/CC layers slot-dies coated from EA:PrOH (1.0:0.06 v:v). FIG. 9B shows the J-V curves for PM6:Y6 devices with (1) PDIN-H/CC layers or (2) CN-PDIN-H/CC layers spin coated from EA:PrOH (1.0:0.06 v:v).

### DETAILED DESCRIPTION

The invention relates to organic semiconductor thin films which are useful, for example, in photovoltaic devices and particularly in printed photovoltaic devices. The disclosure relates more specifically to thin films comprising one or more N-annulated PDI compounds, methods of making films, and particularly to film processing methods that employ green solvents, such as water, aqueous solutions, alcohols, organic esters and ketones and mixtures thereof. More specifically, the disclosure relates to thin films comprising one or more N-annulated PDI compounds and an organic or inorganic base employed to deprotonate and dissolve the N-annulated PDI compound in a selected aqueous or alcohol solvent. In specific embodiments the base is an inorganic carbonate soluble in an appropriate polar solvent. In embodiments, the base is Cs₂CO₃. The disclosure also relates to films made by the methods herein and to film-precursor formulations (e.g., inks) which are solutions in which one or more N-annulated PDI compounds are solubilized by addition of base and from which films can be prepared.

In embodiments, the N-annulated perylene diimide (PDI) compounds have at least one pyrrolic N—H bond. In embodiments, the N-annulated perylene diimide (PDI) compounds have one pyrrolic N—H bond. In specific embodiments, the precursor formulation or ink comprises one or more N-annulated PDI compounds with at least one pyrrolic N—H bond and an organic or inorganic base employed to deprotonate and dissolve the N-annulated PDI compound in a selected aqueous or alcohol solvent. In specific embodiments the base is an inorganic carbonate. In embodiments, the base is Cs₂CO₃. In embodiments, the precursor formulation comprises one or more equivalent of base with respect to the number of pyrrolic N—H bonds in the N-annulated perylene diimide. In embodiments, the precursor formulation comprises one or more equivalents of Cs₂CO₃ with respect to the number of pyrrolic N—H bonds in the N-annulated perylene diimide. In embodiments, when the N-annulated perylene diimide has one pyrrolic N—H bond, the precursor formulation comprises one or more equivalents of Cs₂CO₃ with respect to amount (moles) of N-annulated perylene diimide in the formulation.

More specifically, the disclosure provides a thin film comprising one or more N-annulated perylene diimide (PDI) compounds having a pyrrolic N—H bond and methods for making such films using green solvents.

In embodiments, the N-annulated PDI compound is a compound of Formula I:

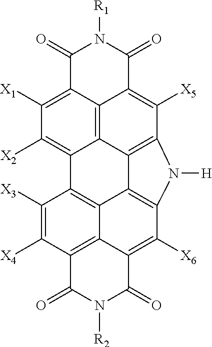

wherein:
R₁ and R₂ are independently a substituted or unsubstituted C₁ to C₁₈ linear or branched alkyl; and
X₁-X₆ are independently selected from H, a C₁-C₆ substituted or unsubstituted alkyl, a halogen (particularly F, Cl, or Br), NO₂, or CN or X₂ and X₃ together form —S—S— and X₁, X₄, X₅ and X₆ are independently selected from H, a C₁-C₆ substituted or unsubstituted alkyl, a halogen (particularly F, Cl, or Br), NO₂, or CN;
wherein optional substitution of alkyl groups is substitution with one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl (including substituted and unsubstituted vinyl), —NHR′ or —NR′R″, wherein R′ and R″ are independently H, an unsubstituted C₁ to C₆ alkyl or a C₁-C₃ halogen-substituted C₁-C₆ alkyl.

In specific embodiments, alkyl substitution is substitution with one or more halogens, —CN, —NO₂, —CF₃, —SO₃H, or —SO₂CF₃. In embodiments, optional substitution of alkyl groups is substitution with one or more halogens. In embodiments, optional substitution of phenyl or benzyl groups is substitution at one to five ring positions with one or more C1-C3 alkyl groups, halogens, —CN, —NO₂, —CF₃, —SO₃H, or —SO₂CF₃. In embodiments, optional substitution of phenyl or benzyl groups is substitution at one to five ring positions with one or more C1-C3 alkyl groups, halogens, or —CN.

In embodiments, R₁ and R₂ are independently unsubstituted C₁ to C₁₈ linear or branched alkyl. In embodiments, R₁ and R₂ are independently unsubstituted C₃ to C₉ branched alkyl. In embodiments, R₁ and R₂ are the same group. In embodiments, R₁ and R₂ are different groups. In embodiments, R₁ and R₂ are the same alkyl group. In embodiments, R₁ and R₂ are different alkyl groups.

In embodiments, all of X₁-X₆ are hydrogen. In embodiments, one of X₁-X₆ is a non-hydrogen group as listed above. In embodiments, one of X₁-X₄ is a non-hydrogen group as listed above. In embodiments, one of X₅ or X₆ is a non-hydrogen group as listed above In embodiments, X₁, X₃ and X₄ are hydrogens and X₂ is a non-hydrogen substituent as listed above. In embodiments, X₂, X₃ and X₄ are hydrogens and X₁ is a non-hydrogen substituent as listed above. In embodiments, one of X₁-X₄ is a halogen. In embodiments, one of X₁-X₄ is —CN. In embodiments, one of X₁-X₄ is —CN and one of X₅ or X₆ is a —CN group. In embodiments, one of X₁-X₄ is a C₁-C₃ unsubstituted alkyl. In embodiments, X₂ or X₁ is selected from a halogen, —CN or an unsubstituted C₁-C₃ alkyl.

In embodiments, X₁-X₆ are independently selected from H, a C₁-C₆ substituted or unsubstituted alkyl, F, Cl, Br, NO₂, or CN and only two of X₁-X₆ are moieties other than H. In embodiments, X₁-X₆ are independently selected from H, a C₁-C₆ substituted or unsubstituted alkyl, F, C, Br, NO₂, or CN and only one of X₁-X₆ is a moiety other than H.

In embodiments, the N-annulated PDI compound is a compound of Formula II:

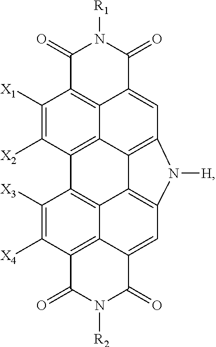

where variables R₁, R₂, and X₁-X₄ are as defined for Formula I including all embodiments thereof. In specific embodiments of Formula II, one of X₁-X₄ is a group other than hydrogen. In specific embodiments of Formula II, one of X₁-X₄ is a halogen, —CN or —NO₂ and the others of X₁-X₄ are hydrogens. In specific embodiments of Formula II, R₁ and R₂ are the same group and are both a branched alkyl group having from 3 to 10 or 3-8 carbon atoms.

In embodiments, the N-annulated PDI compound is compound 1:

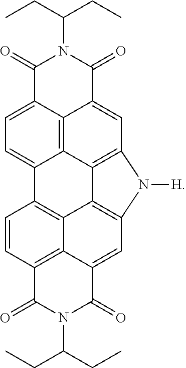

In embodiments, the N-annulated PDI compound is compound 2:

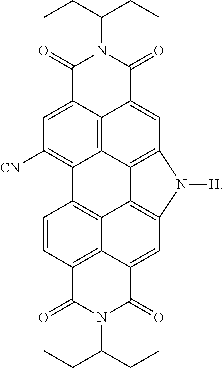

In embodiments, the N-annulated PDI compound is compound 3:

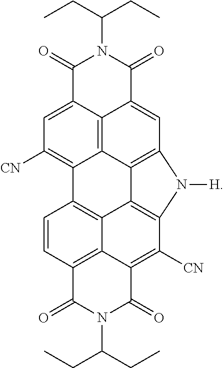

In embodiments, the N-annulated PDI compound is a compound of Formula I or II, wherein X₁ and X₄ are both H, R₁ and R₂ are both unsubstituted alkyl groups having 3 to 8 carbon atoms, X₂ and X₃ are independently selected from H, —CN, —NO₂, or halogen or X₂ and X₃ together form —S—S— and X₅ and X₆ are independently hydrogen, a halogen or —CN. In further embodiments of Formula I or II, one of X₂ or X₃ is —CN, —NO₂ or halogen and the remaining X groups are hydrogen. In further embodiments, one of X₂ or X₃ is Br or Cl. In further embodiments, one of X₅ or X₆ is —CN. In further embodiments, R₁ and R₂ are branched alkyl groups having 3 to 8 carbon atoms. In further embodiments, R₁ and R₂ are unsubstituted branched alkyl groups having 3 to 8 carbon atoms. In further embodiments, R₁ and R₂ are both —CH(C₂H₅)₂.

In an embodiment, the thin film is solvent-resistant. In embodiments, the film is resistant to water, a C₁-C₈ alcohol, an ester, a ketone, a chlorinated alkane, a hydrocarbon, an aromatic hydrocarbon or an amide. In embodiments, the film is resistant to water, a C₁-C₈ alcohol, a chlorinated alkane, a hydrocarbon, an aromatic hydrocarbon or an amide. In embodiments, the thin film is resistant to water, a C₁-C₆ alcohol, dichloromethane, chloroform, hexanes, xylene, benzene, toluene, or dimethylformamide. Resistance to a given solvent can be assessed by noting or measuring changes in film morphology or film properties on contact of the film with a given solvent. In particular, a solvent-resistant film is not measurably dissolved or dissociated on contact with a solvent to which it is resistant. It is noted that films of different N-annulated PDI compounds may be resistant to different solvents. Solvent-resistant films are of particular interest for immiscible solvent processing methods for the construction of layered electronic devices. A solvent-resistant film can be successfully employed in such methods where additional layers are formed upon and in contact with the solvent-resistant film without measurable detriment to the solvent-resistant film.

In embodiments, the thin film ranges in thickness from 1 to 1000 nm thick dependent upon the application. In embodiments, the film ranges in thickness from 1 to 100 nm thick. In embodiments, the thin film ranges in thickness from 5 to 100 nm. Particularly for use in OPV devices, the film thickness ranges from 10 to 50 nm. In embodiments, the film is uniform, such that no feature of the film is greater than 1000 nm in any dimension. In embodiments, no feature of the film is greater than 500 nm in any dimension. In embodiments, no feature of the film is greater than 250 nm in any dimension.

In embodiments, the thin film is formed on and in contact with another layer of thin film, such as by immiscible processing. In an embodiment, the film is formed by printing by any compatible printing process, for example, by slot dye coating. In embodiments, the thin film is formed on and in contact with a photoactive layer, such as a bulk heterojunction layer, in an organic photovoltaic (OPV) device. In an embodiment, the thin film is formed as an electron transport layer (ETL) in a conventional geometry OPV device.

The method for forming a thin film of the disclosure involves providing a film-precursor formulation or an ink which comprises an N-annulated PDI compound having a pyrrole N—H group dissolved in an aqueous or alcohol solvent. The film-precursor formulation or ink is used to form the film by any known compatible film processing method or by any compatible printing method. In embodiments, the film comprises the N-annulated PDI compound and the components of the base added to solubilize the N-annulated PDI compound in the selected green solvent. In embodiments, the film consists essentially of the N-annulated PDI compound and the components of the base added to solubilize the N-annulated PDI compound in the selected green solvent. Such base components can include metal cation components of a base. In specific embodiments, the base comprises Cs₂CO₃. In specific embodiments, the base is Cs₂CO₃ and the film produced comprises Cs. This embodiment does not exclude additives such as plasticizers, surfactants and other surface active materials that are added at levels that do not affect the formation of solutions or films. In embodiments, the films consist of N-annulated PDI compound and the components of the base added to solubilize the N-annulated PDI compound in the selected green solvent. Such base components can include metal cation components of a base. In specific embodiments, the base comprises Cs₂CO₃. In specific embodiments, the base is Cs₂CO₃ and the film comprises Cs. In specific embodiments, the base is Cs₂CO₃ and the film comprises Cs₂CO₃.

More specifically, a thin film of the disclosure is formed by first dissolving a selected amount of the N-annulated PDI compound in a selected amount of a polar solvent and particularly a polar solvent selected from an aqueous solution, a C₁-C₆ alcohol or a miscible combination thereof by addition to the solvent containing the N-annulated compound of an amount of base at least sufficient to polarize the pyrrole N—H bond giving an ionic salt dissolved in the solvent. In embodiments, the solvent is a miscible mixture of C1-C6 alcohols. In embodiments, the solvent is a miscible mixture of C1-C4 alcohols. In embodiments, the solvent is a miscible mixture of C1-C3 alcohols. In embodiments, the solvent is a miscible mixture ethanol and 1-propanol. In embodiments, the polar solvent is a miscible mixture of an aprotic polar solvent, such as an alkyl ester or an alkyl ketone, and one or more C1-C4 alcohols. In embodiments, the polar solvent is a miscible mixture of an aprotic polar solvent, such as an alkyl ester or an alkyl ketone, and one or more C2-C3 alcohols. In embodiments, the polar solvent is a miscible mixture of ethyl acetate or acetone and one or more C2-C3 alcohols. In embodiments, the polar solvent is a miscible mixture of ethyl acetate or acetone and ethanol or 1-propanol. In embodiments, the polar solvent is a miscible mixture of ethyl acetate and ethanol or 1-propanol. In embodiments, the polar solvent is a miscible mixture of acetone and ethanol or 1-propanol. In embodiments, the polar solvent is a miscible mixture of ethyl acetate and 1-propanol.

In embodiment, the polar solvent is a miscible mixture of an alkyl ester or an alkyl ketone, and one or more C1-C4 alcohols wherein the alcohol is present in the mixture at 40% or less by volume. In embodiment, the polar solvent is a miscible mixture of an alkyl ester or an alkyl ketone, and one or more C1-C4 alcohols wherein the alcohol is present in the mixture at 30% or less, 20% or less, 10% or less or 5% or less by volume. In specific embodiments the alkyl ester is ethyl acetate. In specific embodiments, the ketone is acetone. In specific embodiments, the alcohol is ethanol or 1-propanol.

The amount of N-annulated PDI compound dissolved in solution is that amount needed to form a film of desired thickness in a selected amount of solution. The amount of N-annulated PDI needed in the solution for formation of a film of selected thickness can be determined by routine experimentation. The amount of base added to the formulation is an amount sufficient to dissolve the N-annulated PDI compound. Again, the amount of base that is needed to dissolve a selected amount of N-annulated PDI compound can be determined in a selected solvent by routine experimentation. In an embodiment, the amount of base added is about one equivalent (±10%) with respect to the amount (moles) of the N-annulated PDI compound and the number of pyrrole N—H bonds in the N-annulated PDI compound. The number of pyrrole N—H bonds in the N-annulated PDI compound is typically one. In an embodiment, the amount of base added to dissolve the N-annulated PDI compound is at least one equivalent with respect to pyrrole N—H bonds in the N-annulated PDI compound. In embodiments, more than one equivalent of base is added. In embodiments, two or more equivalents of base is added. In embodiments, one to three equivalents of base are added. In embodiments, 1.5 to 2.5 equivalents of base are added.

After preparation of the film-precursor formulation by dissolving the N-annulated PDI compound in selected solvent, a film is formed using any compatible method. The final dried film is formed by removing solvent from the film. In an embodiment, removing solvent from the film as coated, applied or printed results in a solvent-resistant film. In a specific embodiment, the film is formed on and in contact with a photoactive layer, such as a bulk heterojunction (BHJ) layer.

After dissolution of the N-annulated PDI compound in solvent, the solution is optionally filtered to remove particles of a selected high limit of particle size. In embodiments, particles of size of 1 nm or greater are removed. In an embodiment, particle of size greater than 0.5 nm are removed.

In embodiments, the film is formed by spin-coating. In embodiments, the film is formed by slot-die coating. In embodiments, a film is formed by printing. Concentrations of NPDI compound and base in the film precursor formulation are adjusted as known in the art for a given film thickness and film-forming or printing method.

It is believed that addition of base, particularly Cs₂CO₃, to a slurry of N-annulated PDI compound in aqueous or alcoholic solvent results in ionization of the N-annulated PDI compound to form the deprotonated anionic species in solution. Addition of base, as described herein, results in the formation of a solution.

In embodiments, the concentration of N-annulated PDI compound in the solvent ranges from 0.1 to 100 mg/mL. In embodiments, the concentration of N-annulated PDI compound in the solvent ranges from 1 to 100 mg/mL. In embodiments, the concentration of N-annulated PDI in the solvent ranges from 0.5-50 mg/mL. In embodiments, the concentration of N-annulated PDI in the solvent ranges from 5-50 mg/mL. In embodiments, the concentration of N-annulated PDI in the solvent ranges from 10-40 mg/mL. In embodiments, the concentration of N-annulated PDI in the solvent ranges from 0.1-10 mg/mL. In embodiments, the concentration of N-annulated PDI in the solvent ranges from 1-10 mg/mL. In embodiments, the concentration of N-annulated PDI in the solvent ranges from 4-6 mg/mL.

In an embodiment, the thin film is a solvent-resistant, organic semiconducting film comprising non-polymeric perylene diimide molecules with at least one pyrrolic N—H bond. In an embodiment, the thin film is a solvent-resistant, organic semiconducting film comprising non-polymeric perylene diimide molecules with one pyrrolic N—H bond.

In embodiments, the film retains base components that are not removed during solvent removal. Specifically, the thin film at least retains metal ions of the base, and more specifically, when the base is Cs₂CO₃, the film retains Cs ions. In embodiments, the solvent-resistant film comprises an N-annulated PDI compound of Formula I. In embodiments, the solvent-resistant film comprises an N-annulated PDI compound of Formula II.

The term alkyl refers to a monovalent group formally derived from a saturated hydrocarbon group by removal of a hydrogen. A non-cyclic alkyl group has the general formula CₙH₂ₙ₊₁. Alkyl groups can be straight-chain (linear) or branched. Alkyl groups herein can have 1-18 carbon atoms and more preferably 3-13 carbon atoms. Branched alkyl groups herein can have 3-30 carbon atoms and more preferably 3-18 carbon atoms. Straight-chain alkyl groups include those having 1-3 carbon atoms, 1-6 carbon atoms, 1-12 carbon atoms, 1-18 carbon atoms, 4-8 carbon atoms, 6-12 carbon atoms, and 4-12 carbon atoms, among other groups of carbon atom range. Carbon atom range in alkyl groups herein is expresses as a Cx to Cy alkyl group, where x and y are integers representing the number of carbons in the group. Straight-chain alkyl groups include methyl, ethyl, n-propyl, n-hexyl, n-heptyl, etc. individually or in any combination.

Branched alkyl groups include iso-propyl, iso-butyl, sec-butyl, 1-ethylpropyl, 1-propylbutyl, 1-butylpentyl, 1-pentylhexyl, 1-hexylheptyl, 1-heptyloctyl, 1-octylnonyl, 1-nonyldecyl, 2-ethylhexyl individually or in any combination. Branching may occur anywhere along the alkyl chain from the site of attachment of the alkyl group. For example, a branch may occur at the first carbon (as in a 1-ethylpropyl group). The branching can occur for example at the second carbon along the chain (e.g., 2-ethylhexyl). There may be multiple branches along the chain (e.g., 1-ethyl-5-methylhexyl). In specific embodiments, a branched alkyl chain has one branching point which is at the first, second or third carbon from the site of attachment. Alkyl groups herein are optionally substituted. When an alkyl group is described as a Cx to Cy alkyl compound, this encompasses all alkyl groups having x to y carbon atoms including all isomers thereof.

Herein the generic term alkyl groups includes cycloalkyl groups having a carbon ring of 3 or more atoms, typically 3-12 carbon atoms, 3-6 carbon atoms or 3-10 carbon atoms. In specific embodiments, cycloalkyl groups have 3, 4, 5, 6, 7 or 8 member carbon rings. Specific cycloalkyl groups include cyclopropyl, cyclobutyl, cyclopentyl, cyclohexyl, cycloheptyl, cyclooctyl, cyclononyl and cyclodecyl groups. Cycloalkyl groups are optionally substituted. Where a substituent is designated an alkyl group that designation includes cycloalkyl groups. Alkyl groups also include non-cyclic alkyl groups (those not including a carbon ring).

As described herein alkyl groups are optionally substituted with one or more non-hydrogen groups selected from wherein optional substitution of alkyl groups is substitution with one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl (including unsubstituted and substituted vinyl groups), —NHR′ or —NR′R″, wherein R′ and R″ are independently H, an unsubstituted C₁ to C₆ alkyl or a C₁-C₃ halogen-substituted C₁-C₆ alkyl. More preferred substituents are halogen, —CN, —NO₂, —CF₃, —SO₃H, —SO₂CF₃, or —SO₂R′. Yet more preferred substituents are —F, —Cl, —Br, or —CN. In embodiments, alkyl groups carry one of the listed substituents. In embodiments, alkyl groups carry two of the listed substituents. In embodiments, alkyl groups carry three of the listed substituents. In embodiments, alkyl groups are unsubstituted.

The term alkenyl refers to a monovalent group formally derived from an alkene hydrocarbon group by removal of a hydrogen. A non-cyclic alkenyl group with one double bond has the general formula CₙH_{2n-1.} Alkenyl groups can be straight-chain (linear) or branched containing one or more branched alkyl groups. Alkenyl groups herein can have 2-18 carbon atoms, more preferably 2-13 carbon atoms and yet more preferably 2-6 carbon atoms. Branched alkenyl groups include a branched alkyl group and can have 3-30 carbon atoms, more preferably 3-18 carbon atoms and yet more preferably 3-6 carbon atoms. Straight-chain alkenyl groups do not include a branched alkyl group and include those having 2-3 carbon atoms, 2-6 carbon atoms, 2-12 carbon atoms, 2-18 carbon atoms, 4-8 carbon atoms, 6-12 carbon atoms, and 4-12 carbon atoms, among other groups of carbon atom range. Carbon atom range in alkenyl groups herein is expresses as a Cx to Cy alkenyl group, where x and y are integers representing the number of carbons in the group. Alkenyl groups include those with one or more double bonds and in particular those with one double bond and/or those with two double bonds. Exemplary alkenyl groups include ethenyl (vinyl), 1-propenyl, 1-hexenyl, 2-hexenyl, 3-hexenyl, 1-heptenyl, 2-methyl propenyl, among others. Branched alkyl groups include 1,2-dimethylpropenyl, 2,2-dimethylethenyl, 2-methylbutenyl, 2,3-dimethylhexen(2) yl, 1-ethylbuten(1)yl, among others. Alkenyl groups herein are optionally substituted. When an alkenyl group is described as a Cx to Cy alkenyl compound, this encompasses all alkenyl groups having x to y carbon atoms including all isomers thereof. Alkenyl groups include cis and trans isomers and mixtures thereof. The generic term alkenyl groups includes cycloalkenyl groups having a carbon ring of 3 or more atoms, typically 3-12 carbon atoms, 3-6 carbon atoms or 3-10 carbon atoms. In specific embodiments, cycloalkenyl groups have 3, 4, 5, 6, 7 or 8 member carbon rings. Specific cycloalkenyl groups include cyclopropenyl, cyclobutenyl, cyclopentenyl, cyclohexenyl, cycloheptenyl, cyclooctenyl, cyclononenyl and cyclodecenyl groups.

Cycloalkenyl groups are optionally substituted. Where a substituent is designated an alkenyl group that designation includes cycloalkenyl groups. Alkenyl groups also include non-cyclic alkenyl groups (those not including a carbon ring).

The terms benzyl, phenyl and vinyl groups as used herein have their art-recognized meaning. Benzyl, phenyl and vinyl groups herein are optionally substituted and include substituted and unsubstituted benzyl, phenyl and vinyl groups. Phenyl and benzyl groups are optionally substituted with 1-5 non-hydrogen ring substituents, which include one or more halogens, —CN, —NO₂, C1-C6 alkyl, C2-C6 alkenyl, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl (including unsubstituted and substituted vinyl groups), —NHR′ or —NR′R″, wherein R′ and R″ are independently H, an unsubstituted C₁ to C₆ alkyl or a C₁-C₃ halogen-substituted C₁-C₆ alkyl. More preferred ring substituents are halogen, —CN, —NO₂, —CF₃, —SO₃H, —SO₂CF₃, or —SO₂R′. Yet more preferred ring substituents are —F, —Cl, —Br, or —CN. In embodiments, substituted phenyl or benzyl groups carry one of the listed ring substituents. In embodiments, substituted phenyl or benzyl groups carry two of the listed substituents. In embodiments, substituted phenyl or benzyl groups carry three of the listed substituents. In embodiments, substituted phenyl or benzyl groups carry four of the listed substituents. In embodiments, substituted phenyl or benzyl groups carry five of the listed substituents. In embodiments, phenyl groups are unsubstituted. In embodiments, benzyl groups are unsubstituted. In embodiments, vinyl groups are unsubstituted. Exemplary ring substituted phenyl and benzyl groups include among others pentafluorophenyl, pentafluorbenzyl, 4-chlorophenyl, 4-chlorobenzyl, 2-methylphenyl, 2-methylbenzyl, 3-cyanophenyl, and 3-cyanobenzyl. Vinyl groups herein are optionally substituted with 1-3 non-hydrogen substituents and the methylene group of benzyl groups herein are optionally substituted with one or two non-hydrogen substituents which include one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, —NHR′ or —NR′R″, wherein R′ and R″ are independently H, or a C₁-C₃ halogen-substituted C₁-C₆ alkyl. More preferred substituents are halogen, —CN, —NO₂, —CF₃, —SO₃H, —SO₂CF₃, or —SO₂R′. Yet more preferred substituents are —F, —Cl, —Br, or —CN.

As to any of the above groups which contain one or more substituents, it is understood, that such groups do not contain any substitution or substitution patterns which are sterically impractical and/or synthetically non-feasible. In addition, the compounds of this disclosure include all stereochemical isomers arising from the substitution of these compounds.

With respect to the various compounds of the disclosure, the atoms therein may have various isotopic forms (e.g., isotopes of hydrogen include deuterium and tritium). All isotopic variants of compounds of the disclosure are included within the disclosure and particularly include deuterium and ¹³C isotopic variants. It will be appreciated that such isotopic variants may be useful for carrying out various chemical and biological analyses, investigations of reaction mechanisms and the like. Methods for making isotopic variants are known in the art.

Compounds of the disclosure can be prepared by one of ordinary skill in the art in view of the descriptions provided herein and what is known in the art from commercially or otherwise readily available starting materials and reagents. As described herein in the Examples, known synthetic methods can be readily adapted for synthesis of the compounds of the formulas herein.

In embodiments, the N-annulated PDI compounds herein are not soluble in alcohol or water or aqueous solution at a sufficiently high amount to allow formation of a film of desired thickness and concentration of NPDI compound from the selected solvent.

Addition of base results in solubilization of the N-annulated PDI compound(s). Films herein may be prepared from solutions containing more than one NPDI compound and containing one base or a mixture of bases. In a specific embodiment, the base comprises Cs₂CO₃ alone or in combination with another inorganic or organic base. In embodiments, the base comprises Cs₂CO₃ in combination with another inorganic or organic base which is soluble in the solvent employed (e g., water, aqueous solution, alcohol or a mixture thereof). In embodiments, films herein are prepared from solutions in which Cs₂CO₃ is the only added base.

A chemical compound or salt is typically considered soluble in a given solvent at a given temperature and pressure if 1 g or more of the compound or salt can be dissolved in 100 mL of the solvent. A chemical compound or salt is typically considered slightly soluble in a given solvent at a given temperature and pressure if 0.1 g to less than 1 g of the compound or salt can be dissolved in 100 mL of the solvent. A chemical compound or salt is typically considered insoluble at a given temperature and pressure, if less than 0.1 g of the compound or salt can be dissolved in 100 mL of the solvent. Herein, the level of solubility of components in film precursor formulations required is that level that is sufficient to allow formation of a film of desired thickness by a selected film deposition method at a given temperature and pressure (e.g., spin coating, or slot-dye methods). The solvent should dissolve the combination of NPDI compound needed to form the film of desired thickness and the number of equivalents of base (e.g., Cs₂CO₃) needed to facilitate deprotonation and dissolution of the NPDI compound. Preferably, films of this disclosure formed from such film precursor solutions are formed and processed at room temperature and normal atmospheric pressure. It is generally recognized that the concentration of components in film precursor solutions affects film thickness. For given components and a given film formation method, the component concentrations needed to achieve a desired film thickness can be determined routinely by methods known in the art. In embodiments of methods herein, film precursor formulation in polar solvents (e.g., water, alcohols, esters, or mixtures thereof) contain the N-annulated PDI compound, such as compound 1 or compound 2, at levels of 0.1 mg/mL or higher. Thus, the solubility of the N-annulated PDI compound on addition of base (specifically Cs₂CO₃) should preferably be 0.1 mg/mL or higher. In specific embodiments, film precursor formulation in polar solvents (e.g., water, alcohols, esters, ketones or mixtures thereof) contain the N-annulated PDI compound, such as compound 1, at levels between 0.1 and 10 mg/mL, inclusive. In specific embodiments, film precursor formulation in polar solvents (e.g., water, alcohols, esters, ketones or mixtures thereof) contain the N-annulated PDI compound, such as compound 1, at levels between 0.1 and 5 mg/mL, inclusive. In specific embodiments, film precursor formulation in polar solvents (e.g., water, alcohols, esters or mixtures thereof) contain the N-annulated PDI compound, such as compound 1, at levels between 0.2 and 1 mg/mL, inclusive.

Base is added to formulations, including inks, herein to facilitate dissolution of N-annulated PDI compounds in the formulation. Any base that can function to deprotonate the pyrrolic N—H bond of the N-annulated PDI compound can be used. Unexpectedly improved inks for formation of thin films for use in multilayer electronic devices, such as OPVs are produced employing Cs₂CO₃ as the added base or as a component of the added base. The base, for example, can be any source of carbonate that is soluble in the chosen polar solvent (e.g., aqueous, alcoholic, ester or ketone solvent) at a level that facilitates dissolution of the amount of N-annulated PDI compound for forming a film of desired thickness.

In specific embodiments, the solvent is a miscible mixture of (1) an ester or ketone solvent in which the base (particularly Cs₂CO₃) is at most slightly soluble with (2) a different polar solvent in which the base (particularly Cs₂CO₃) is at least soluble. The second polar solvent is added to the ester or ketone solvent (providing a miscible mixed solvent) to facilitate solubilization of the base, particularly Cs₂CO₃. In embodiments, the amount of the second polar solvent added to the ester or ketone solvent is the minimum volume of that second solvent that dissolves the desired amount of base (particularly Cs₂CO₃). In embodiments, the amount of second polar solvent added to the ester or ketone solvent is 40% or less by total volume of solvent. In embodiments, the amount of second polar solvent added to the ester or ketone solvent is 30% or less, 20% or less, 10% or less, or 5% or less by total volume of solvent. In embodiments, the amount of second polar solvent added to the ester or ketone solvent at a volume between 5% and 1% by total volume of solvent. In embodiments, the amount of second polar solvent added to the ester or ketone solvent is 1% or less by total volume of solvent. In specific embodiments, the ester solvent is ethyl acetate. In specific embodiments, the ketone solvent is acetone. In specific embodiments, the ester solvent is ethyl acetate and the second polar solvent is ethanol or 1-propanol. In specific embodiments, the ketone solvent is acetone and the second polar solvent is ethanol or 1-propanol.

Additional polar solvents in which Cs₂CO₃ is soluble include water, dimethylforamide, dimethylsulfoxide, sulfolane and methylpyrrolidone. These polar solvent have limited volatility at room temperature and 1 atmosphere pressure and as such may detrimentally effect film formation if added to solvent used in methods herein in too high a volume. In these cases, it is preferred to use the minimal amount of polar solvent needed to dissolve the amount of Cs₂CO₃ to be added to the formulation (e.g., ink).

In specific embodiments, the solvent is an ester or ketone solvent to which an alkyl alcohol is added to facilitate solubilization of the base, particularly Cs₂CO₃. In embodiments, the amount of alkyl alcohol added to the ester or ketone solvent is the minimum volume of that alkyl alcohol that dissolves the desired amount of base (particularly Cs₂CO₃). In embodiments, the amount of alkyl alcohol added to the ester or ketone solvent is 40% or less by total volume of solvent. In embodiments, the amount of alkyl alcohol added to the ester or ketone solvent is 30% or less, 20% or less, 10% or less, or 5% or less by total volume of solvent. In embodiments, the amount of alkyl alcohol added to the ester or ketone solvent is between 5% and 1% by total volume of solvent. In embodiments, the amount of alkyl alcohol added to the ester or ketone solvent is 1% or less by total volume of solvent. In specific embodiments, the ester solvent is ethyl acetate. In specific embodiments, the ketone solvent is acetone. In specific embodiments, the ester solvent is ethyl acetate and the alkyl alcohol is ethanol or 1-propanol. In specific embodiments, the ketone solvent is acetone and the alkyl alcohol is ethanol or 1-propanol.

In specific embodiments, the base is an inorganic base, such as an alkali metal hydroxide or an alkaline earth metal hydroxide. In specific embodiments, the base is an alkali metal carbonate or an alkaline earth metal carbonate. In a specific embodiment, the base is cesium carbonate or a combination of cesium carbonate with another base. In a specific embodiment, the base comprises cesium carbonate. In an embodiment, the base consists essentially of cesium carbonate. In an embodiment, the base consists of cesium carbonate. In a specific embodiment, the base is cesium carbonate or a combination of cesium carbonate with another carbonate base.

In embodiments, the base can be an ammonium hydroxide and more particularly an alkyl ammonium hydroxide base. The term ammonium refers to the (R)₄N⁺ cation, where each R is independently H or an alkyl group. In embodiments, the base can be a quaternary alkyl ammonium hydroxide. Preferred alkyl groups for ammonium compounds are C₁-C₆ alkyl groups and more preferred are C₁-C₄ alkyl groups. Tin embodiments, the base can be an organic base, such as an amine. In specific embodiments, the amine is an alkyl amine, which includes a monoalkyl amine (a primary amine), dialkyl amine (a secondary amine) or a trialkyl amine (a tertiary amine). In specific embodiment, the base is a primary amine. In embodiments, the primary amine is a C₁-C₆ alkyl primary amine (NH₂R, where R is a C₁-C₆ alkyl group).

The base may be a solid, liquid or a gas at ambient temperatures. A base that is a gas can be contacted with the solvent by bubbling the gas through the solvent, for example. The base is preferably soluble in the aqueous or alcoholic or ester solvent used in the formulation at the concentration at which it is added to the formulation. In general, base is added to a given formulation in an amount that dissolves the N-annulated PDI compound. In specific embodiments, the amount of base added is at least about one equivalent (±10%) of base with respect to the number of pyrrolic N—H bonds in the N-annulated PDI compound in the solvent. In specific embodiments, the amount of base added to the formulation is one equivalent (±10%) with respect to the number of pyrrolic N—H bonds in the N-annulated PDI compound in the solvent. In specific embodiments, the amount of base added to the formulation is at least two equivalents, or at least 3 equivalents (±10%) with respect to the number of pyrrolic N—H bonds in the N-annulated PDI compound in the solvent. In specific embodiments, the amount of base added to the formulation is at least two equivalents, or at least 3 equivalents (±10%), but less than 5 equivalents (±10%), with respect to the number of pyrrolic N—H bonds in the N-annulated PDI compound in the solvent.

The base is preferably cesium carbonate which is soluble in water, certain alcohols and certain other polar solvents. In general, cesium carbonate is added to a given formulation in an amount that dissolves the N-annulated PDI compound added to the formulation. In specific embodiments, the amount of cesium carbonate added is at least about one equivalent (±10%) of base with respect to the amount of the N-annulated PDI compound and number of pyrrolic N—H bonds in the N-annulated PDI compound in the solvent. When the number of pyrrolic N—H bonds in the N-annulated PDI compound is one then the base is added with respect to the number of equivalents (±10%) of the PDI compound in the formulation. In specific embodiments, the amount of cesium carbonate added to the formulation is one equivalent (±10%) with respect to amount of and the number of pyrrolic N—H bonds in the N-annulated PDI compound in the solvent. In specific embodiments, the amount of base added to the formulation is at least two equivalents, or at least 3 equivalents (±10%) with respect to the amount and number of pyrrolic N—H bonds in the N-annulated PDI compound in the solvent. In specific embodiments, the amount of base added to the formulation is at least two equivalents, or at least 3 equivalents (±10%), but less than 5 equivalents (±10%), with respect to the amount and number of pyrrolic N—H bonds in the N-annulated PDI compound in the solvent. In specific embodiments, the amount of cesium carbonate added is about one equivalent (±10%) of base with respect to the amount of the N-annulated PDI compound and number of pyrrolic N—H bonds in the N-annulated PDI compound in the solvent. In specific embodiments, the amount of cesium carbonate added is about two equivalents (±10%) of base with respect to the amount of the N-annulated PDI compound and number of pyrrolic N—H bonds in the N-annulated PDI compound in the solvent. In specific embodiments, where the NPDI compound has one pyrrolic N—H bond, the amount of cesium carbonate added is about one equivalent (±10%) of base with respect to the amount of the N-annulated PDI compound to be dissolved in the solvent. In specific embodiments, where the NPDI compound has one pyrrolic N—H bond, the amount of cesium carbonate added is about two equivalents (±10%) of base with respect to the amount of the N-annulated PDI compound to be dissolved in the solvent. In specific embodiments, where the NPDI compound has one pyrrolic N—H bond, the amount of cesium carbonate added is between about 1.5 and about 3 equivalents (±10%) of base with respect to the amount of the N-annulated PDI compound to be dissolved in the solvent.

In specific embodiments, the base is a combination of Cs₂CO₃ with another base. In specific embodiments, the base is a combination of Cs₂CO₃ with another base wherein the combination of bases is soluble in the selected aqueous, alcoholic or ester solvent or mixture of such solvents. In specific embodiments, the base is a combination of Cs₂CO₃ with another carbonate base wherein the combination of bases is soluble in a selected aqueous, alcoholic or ester solvent or mixture of such solvents. In specific embodiments, the base is more than 50 mole % Cs₂CO₃. In specific embodiments, the base is more than 75 mole % Cs₂CO₃. In specific embodiments, the base is more than 90 mole % Cs₂CO₃. In specific embodiments, the base is more than 95 mole % Cs₂CO₃. In specific embodiments, the base is more than 99 mole % Cs₂CO₃.

Solvents of the formulations, including inks, herein are most generally green solvents and include water, C₁-C₈ alcohols, C₂-C₈ esters and miscible mixtures thereof, among others. Useful solvents include polar solvents and polar aprotic solvents or mixtures thereof. More specifically, the solvents are water, aqueous solutions, alcohols, esters, ketones miscible mixtures of water with alcohol, miscible mixtures of water with ester, miscible mixtures of water with ketone, miscible mixtures of different alcohols, miscible mixtures of different ketones, miscible mixtures of alcohol and ester, miscible mixtures of alcohol and ketone, miscible mixtures of ester and ketone. In specific embodiments, the solvent is a C₂-C₆ alcohol or a miscible mixture thereof. In specific embodiments, the solvent is a C₂-C₄ alcohol or a miscible mixture thereof. In specific embodiments, the solvent is a miscible mixture of one or more alcohols and one or more esters. In specific embodiments, the solvent is a miscible mixture of one or more alcohols and one or more ketones. In specific embodiments, the solvent is water, a C₂ to C₆ alcohol or any miscible mixtures thereof. In specific embodiments, the solvent is water, a C₂ to C₄ alcohol or any miscible mixtures thereof. In specific embodiments, the solvent is 1-propanol. In specific embodiments, the solvent is ethanol.

In specific embodiments, the solvent is a miscible mixture of 1-propanol with ethanol, 2-propanol (i.e., isopropyl alcohol) or a butanol (any one or more of 1-butanol, 2-butanol, 2-methyl-1-propanol (sec-butyl alcohol) or 2-methyl-2propanol (tert-butyl alcohol)). In embodiments, the solvent is a miscible mixture of 1-propanol with ethanol. In embodiments, the miscible mixture of 1-propanol and ethanol, the volume ratio of 1-propanol to ethanol ranges from 5 to 0.2. In embodiments, the miscible mixture of 1-propanol and ethanol, the volume ratio of 1-propanol to ethanol ranges from 3 to 0.3. In embodiments, the miscible mixture of 1-propanol and ethanol, the volume ratio of 1-propanol to ethanol is 1+/−10%. In embodiments, the miscible mixture of 1-propanol and ethanol, the volume ratio of 1-propanol to ethanol is 3+/−10%. In embodiments, the miscible mixture of 1-propanol and ethanol, the volume ratio of 1-propanol to ethanol is 2+/−10%.

In embodiments, the solvent is a miscible mixture of 1-propanol with 2-propanol. In embodiments, the miscible mixture of 1-propanol and 2-propanol, the volume ratio of 1-propanol to 2-propanol ranges from 5 to 0.2. In embodiments, the miscible mixture of 1-propanol and 2-propanol, the volume ratio of 1-propanol to 2-propanol ranges from 3 to 0.3. In embodiments, the miscible mixture of 1-propanol and 2-propanol, the volume ratio of 1-propanol to 2-propanol is 1+/−10%. In embodiments, the miscible mixture of 1-propanol and 2-propanol, the volume ratio of 1-propanol to 2-propanol is 3+/−10%.

In embodiments, the miscible mixture of 1-propanol and 2-propanol, the volume ratio of 1-propanol to 2-propanol is 2+/−10%.

In embodiments, for use in solvents herein the ester solvent is an ester or mixture of esters having 1 to 6 carbon atoms. In embodiments for solvents herein, the ester solvent has formula R₄—CO—OR₅, where R₄ is H or an alkyl group having 1-3 carbon atoms and R₅ is an alkyl group having 1-4 carbon atoms. In embodiments, the ester solvent is an acetate ester. In embodiments, the ester solvent is a formate ester. In embodiments, the ester solvent is ethyl acetate or methyl acetate. In embodiments, the ester solvent is methyl formate or ethyl formate.

In embodiments, for use in solvents herein the ketone solvent or a ketone or mixture of ketones. In embodiments, the ketone has 2 to 6 carbon atoms. In embodiments, the ketone has formula R₆—CO—OR₇, where R₆ and R₇ are independently an alkyl group having 1-4 carbon atoms. In embodiments, the ketone has formula R₆—CO—OR₇, where R₆ and R₇ are independently an alkyl group having 1-4 carbon atoms and the total number of carbons in the ketone is 2 to 6. In embodiments, the ketone is acetone or methylethylketone.

In embodiments, the solvent of the formulation is an ester or a mixture of esters having a sufficient amount of an alcohol or water or other second polar solvent therein such that amount of base, particularly Cs₂CO₃, added to the solvent mixture is dissolved therein. In embodiments, the volume ratio of ester solvent to second solvent ranges from 20:1 to 15:1. In embodiments, the volume ratio of ester solvent to second solvent ranges from 18; 1 to 16:1. In embodiments, the ester is ethyl acetate or methyl acetate. In embodiments, the second solvent added is an alcohol selected from methanol, ethanol, propanol all isomers thereof (1-propanol or 2-propanol (isopropanol)), butanol all isomers thereof (1-butanol, 2-butanol, 2-methylpropan-1-ol, t-butanol) or mixtures thereof. In embodiments, the alcohol added to the ester or mixture of esters is methanol, ethanol, 1-propanol, 2-propanol, or t-butanol or a mixture thereof. In specific embodiments, the ester is ethyl acetate and the alcohol is ethanol, 1-propanol, 2-propanol or t-butanol or a mixture thereof. In specific embodiments, the ester is ethyl acetate and the alcohol is ethanol, 1-propanol, 2-propanol or a mixture thereof. In specific embodiments, the ester is ethyl acetate and the alcohol is 1-propanol, 2-propanol or a mixture thereof. In specific embodiments, the ester is ethyl acetate and the alcohol is 1-propanol.

In embodiments, the solvent of the formulation is a ketone or a mixture of ketones having a sufficient amount of an alcohol or water or another second polar solvent therein such that amount of base, particularly Cs₂CO₃, added to the solvent mixture is dissolved therein. In embodiments, the volume ratio of ketone solvent to second polar solvent ranges from 20:1 to 15:1. In embodiments, the volume ratio of ester solvent to second polar solvent ranges from 18; 1 to 16:1. In embodiments, the ketone is acetone or methylethylketone. In embodiments, the alcohol added to solubilize the base added is methanol, ethanol, propanol all isomers thereof (1-propanol or 2-propanol (isopropanol)), butanol all isomers thereof (1-butanol, 2-butanol, 2-methylpropan-1-ol, t-butanol) or mixtures thereof. In embodiments, the alcohol added to the ester or mixture of esters is methanol, ethanol, 1-propanol, 2-propanol, or t-butanol or a mixture thereof. In specific embodiments, the ester is ethyl acetate and the alcohol is ethanol, 1-propanol, 2-propanol or t-butanol or a mixture thereof. In specific embodiments, the ester is ethyl acetate and the alcohol is ethanol, 1-propanol, 2-propanol or a mixture thereof. In specific embodiments, the ester is ethyl acetate and the alcohol is 1-propanol, 2-propanol or a mixture thereof. In specific embodiments, the ester is ethyl acetate and the alcohol is 1-propanol.

In specific embodiments, solvents used in formulations herein for film formation or printing have boiling points at 1 atmosphere of 100° C. or less. In more specific embodiments, solvents used in formulations herein for film formation or printing have boiling points at 1 atmosphere between 40° C. and 85° C. In more specific embodiments, solvents used in formulations herein for film formation or printing have boiling points at 1 atmosphere between 40° C. and 80° C. In more specific embodiments, solvents used in formulations herein for film formation or printing have boiling points at 1 atmosphere between 50° C. and 85° C. In more specific embodiments, solvents used in formulations herein for film formation or printing have boiling points at 1 atmosphere between 50° C. and 80° C.

Film-precursor formulations herein may further comprise one or more functional additives that facilitate film formation or function. Ink formulations herein may further comprise one or more functional additives that facilitate use of the ink for printing. Formulations herein may, for example, comprise one or more surfactants, biocides, corrosion inhibitors, plasticizers, viscosity modifiers, other colorants or the like. However, the predominant components of the formulations herein are solvent, N-annulated PDI (or the anion thereof) and base, particularly Cs₂CO₃. In embodiments, combined additives in a formulation represent less than about 10% by weight of the weight of N-annulated PDI in the formulation. In embodiments, combined additives in a formulation represent less than about 5% by weight of the weight of N-annulated PDI in the formulation. In embodiments, combined additives in a formulation represent less than about 1% by weight of the weight of N-annulated PDI in the formulation.

In embodiments, solutions for film formation may be filtered prior to film formation using appropriate filtration media to remove undesired particulate or other solid materials.

Any method known in the art for forming thin films which can employ aqueous, alcoholic, ester or ketone solutions for film formation can be employed herein. In specific embodiments, films are formed by spin coating. In embodiments, films are formed by slot-die methods.

Films of this disclosure can be employed, for example, as an electron acceptor in electronic devices. Exemplary electronic devices include among others OPVs, an organic thin film transistor, a Li-ion battery. Those of ordinary skill in the art will appreciate that methods for the preparation of OPVs, organic thin film transistors and Li-ion batteries and other electronic devices that employ electron acceptor films are known in the art and can be applied employing materials of the formulas herein. In view of what is known in the art and what is described herein one of ordinary skill in the art can employ materials described and characterized herein in such devices without resort to undue experimentation.

The films and film-precursor formulations of the disclosure, and particularly films that are solvent-resistant are useful in the manufacture of OPV devices, particularly as an electron transporting layer in such devices. In specific embodiments, the films and film-precursor solutions herein are useful for preparation of one or more electron transporting layer (ETL, also designated electron extraction layer (EEL)) which is/are sandwiched between a photoactive layer and top cathode (conventional OPV device). The ETL facilitates the transfer of electrons from the photoactive layer to the cathode in an OPV device.

The disclosure additionally provides an OPV device which comprises a film comprising one or more N-annulated PDI compounds having at least one pyrrolic N—H bond. In specific embodiments, the NPDI film is employed as an ETL in an OPV device. In embodiments, the NPDI film ETL is positioned between a photoactive layer and a cathode layer in the OPV device. In related embodiments, the disclosure provides a method of constructing an OPV device containing one or more ETL, wherein the ETL is an NPDI film. In embodiments, the ETL is an NDPI film formed from an aqueous or alcoholic solution as described herein. In embodiments, the ETL is an NDPI film formed from an aqueous or alcoholic solution as described herein on and in contact with a photoactive layer. In other related embodiments, the disclosure provides a method for operating an OPV device containing one or more ETL, wherein the ETL is an NPDI film.

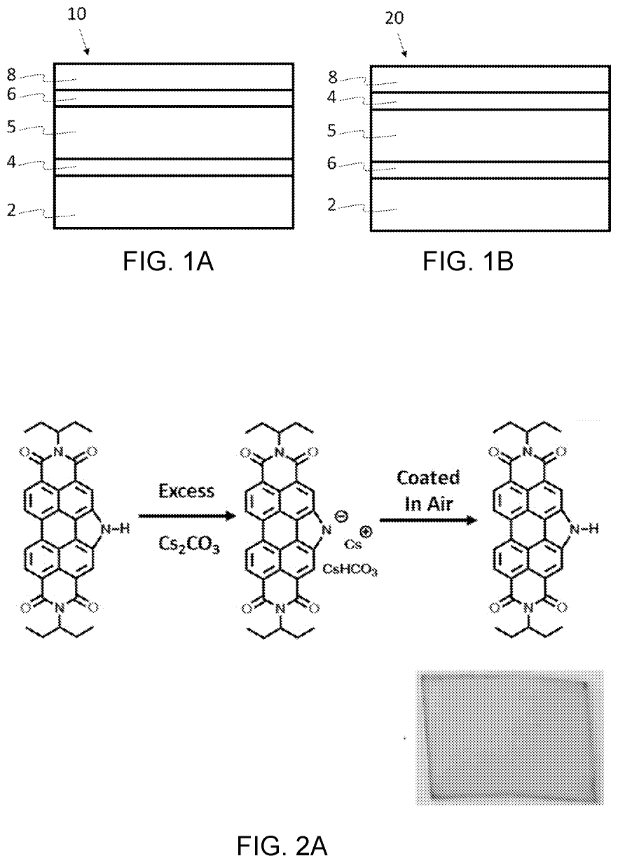

OPV cells typically have layered structures, as illustrated in FIGS. 1A and 1B, where a photoactive layer is sandwiched between two electrodes (often designated a top and bottom electrode). An electron transport layer (ETL) (also called an electron extraction layer (EEL)) and a hole transport layer (HTL) (also called a hole extraction layer (HEL)) facilitate efficient charge extraction between the active layer and the electrodes. In embodiments, herein the HTL is optional, however preferred. There are two different OPV geometries: conventional (normal or non-inverted) and inverted, the structures of which are known in the art. The difference between the conventional and inverted device architecture is the direction of the charge extraction. For example, in the conventional geometry electrons are extracted from the top metal electrode which should have a lower work function (n-type side) than the bottom electrode. In the inverted geometry, electrons are extracted from the bottom electrode (e.g., the ITO electrode) which should then have the lower work function (n-type side).

The work function of an electrode defines the type of contact with the semiconductor. For example, if ohmic contact (which is desirable) is needed on the n-type side of an OPV, the work function of the metal electrode should be lower than the work function of the n-type semiconductor and the reverse for metal and p-type semiconductor. To achieve ohmic contacts on the p-type side of an OPV, higher work-function metals are typically used. The work function of the electrodes, e.g., (ITO or any metal), however, can be tuned to work in either inverted or conventional geometries by selection of the interlayers (ETL and HTL). A description of the work function of electrodes related to electrodes for organic electronics and how such tuning can be obtained is given by Zhou et al [Zhou et al., 2012 Science. 336 (6079): 327-332.]

In conventional cells, indium tin oxide (ITO) is typically used as the anode and a metal with a lower work function than ITO (e.g., aluminum) is employed as the cathode. In inverted cells, the cathode is usually ITO and the anode is a metal with a work function higher than ITO (e.g., silver). Inverted OPV devices are generally more stable and show higher efficiencies. Interfacial layers can significantly improve the function of OPV cells. [Lai et al. Materials Today 2013, 16 (11): 424-432.] NPDI films of this disclosure can be employed as interfacial layers in OPV devices. NPDI films of this invention can be employed in particular as ETL in OPV. Note that OPV devices may contain one or more NPDI films as interfacial layers in OPV devices.

Additional details of the structure and manufacture of OPV devices and interfacial layers therein are provided in references cited herein, such as Lai et al. Materials Today 2013, 16(11): 424-432. Each such reference is incorporated by reference herein in its entirety for descriptions of materials used in constructing OPV devices, including The variation in device architecture, conductive electrodes, materials for hole transport layers, materials for photoactive layers, materials for the bulk heterojunction BHJ and top metal electrode and more particularly for the use of ETLs in such devices. Additional details of the synthesis, characterization and application of N-annulated PDI materials and films thereof are provided in references cited herein and any supporting information of each of these references, which is freely available on-line for the publisher. Each cited reference herein, including any electronic supplemental information thereof, providing such additional description is incorporated by reference herein in its entirety for descriptions of film making techniques and methods for fabrication electronic devices incorporating such films.

Additional details of processing of materials, such as N-annulated PDI materials and films thereof of the disclosure, and the preparation of devices, such as organic solar cells are provided in certain references cited herein and any supporting information of each of these references which is freely available on-line for the publisher. Each of the references cited herein and any corresponding supporting information is incorporated by reference herein in its entirety for such additional details including synthetic methods for starting materials, purification methods, characterization of compounds, processing of materials, components of devices employing these materials and methods for such characterization, construction and testing of OPVs, as well as structure and components of OPVs.

ETL herein are layers in multilayer organic electronic devices such as OPVs and OLEDs. Solution deposition methods for formation of thin layers can be applied to prepare the ETL layers herein from film precursor formulations described herein. Coating methods including spin coating spray coating (including ultrasonic spray coating) and slot die coating can be applied. In certain coating methods, patterned coating methods can be employed to generate a desired 2-D or 3-D pattern of layer deposition. In addition various printing methods can be applied for ETL preparation, including among others, ink-jet printing and screen printing methods can be employed. One of ordinary skill in the art in view of what is known in the art about such coating and printing methods and the application of such methods to the formation of uniform thin films from solutions, particularly in view of the disclosures herein, can apply and or routinely adapt such known methods for preparation of ETL as described herein.

All references throughout this application, for example patent documents including issued or granted patents or equivalents; patent application publications; and non-patent literature documents or other source material; are hereby incorporated by reference herein in their entireties, as though individually incorporated by reference.

All patents and publications mentioned in the specification are indicative of the levels of skill of those skilled in the art to which the disclosure pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

The description herein may refer to a color of a film, solution or liquid phase. When provided such color designations are based on visual observation of the item begin described or a photograph of such item by a person believed to have normal color vision. It will be appreciated that the color description given are subjective to the observer. This, designations including yellow, reddish orange, and purple among others should be considered approximations of the actual color of the item described. UV-vis spectra of films, solutions and liquid phases, which are provided in some cases herein, provide a quantitative method for assessment of the color of a given item. In visual colorimetric detection methods herein the color change indicative of the presence of amines is described as a change from reddish orange/red to purple. This color change may be described differently by different individual observers.

When a group of substituents is disclosed herein, it is understood that all individual members of those groups and all subgroups, including any isomers and enantiomers of the group members, and classes of compounds that can be formed using the substituents are disclosed separately. When a compound is claimed, it should be understood that compounds known in the art including the compounds disclosed in the references disclosed herein are not intended to be included. When a Markush group or other grouping is used herein, all individual members of the group and all combinations and subcombinations possible of the group are intended to be individually included in the disclosure.

Every formulation or combination of components described or exemplified can be used to practice the disclosure, unless otherwise stated. Specific names of compounds are intended to be exemplary, as it is known that one of ordinary skill in the art can name the same compounds differently. When a compound is described herein such that a particular isomer or enantiomer of the compound is not specified, for example, in a formula or in a chemical name, that description is intended to include each isomers and enantiomer of the compound described individual or in any combination.

It will be appreciated by one of ordinary skill in the art that all numbers expressing a quantity, volume, percentage with respect to a formulation or composition or a property or parameter of a compound or device include some level of variance. For improved clarity herein, all numbers given in the specification unless otherwise include the specific value and include a range of +/−10% of the value given. The term “about” can be added to any value given herein for any quantity or parameter and the term “about” then refers to the range of +/−10% of the value given.

One of ordinary skill in the art will appreciate that methods, process conditions, concentration, device elements, starting materials, and synthetic methods other than those specifically exemplified can be employed in the practice of the disclosure without resort to undue experimentation. All art-known functional equivalents, of any such methods, device elements, starting materials, and synthetic methods are intended to be included in this disclosure. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. For compositions as claimed herein, the term consisting essentially of excludes any component that detrimentally and materially affects the properties of that composition for use in an application recited herein, such as use of the composition as an electron acceptor particularly in an electronic device or more specifically in a thin film transistor, or a Li-ion battery.

Any recitation herein of the term “comprising”, particularly in a description of components of a composition or in a description of elements of a device, is understood to encompass those compositions and methods consisting essentially of and consisting of the recited components or elements. The disclosure illustratively described herein suitably may be practiced in the absence of any element or elements, limitation or limitations which is not specifically disclosed herein.

Without wishing to be bound by any particular theory, there can be discussion herein of beliefs or understandings of underlying principles relating to the disclosure. It is recognized that regardless of the ultimate correctness of any mechanistic explanation or hypothesis, an embodiment of the disclosure can nonetheless be operative and useful.

The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure claimed. Thus, it should be understood that although the present disclosure has been specifically disclosed by preferred embodiments and optional features, modification and variation of the concepts herein disclosed may be resorted to by those skilled in the art, and that such modifications and variations are considered to be within the scope of this disclosure.

### THE EXAMPLES

### Example 1: Film Formation Employing PDIN-H with Cs₂CO₃ in 1-Propanol

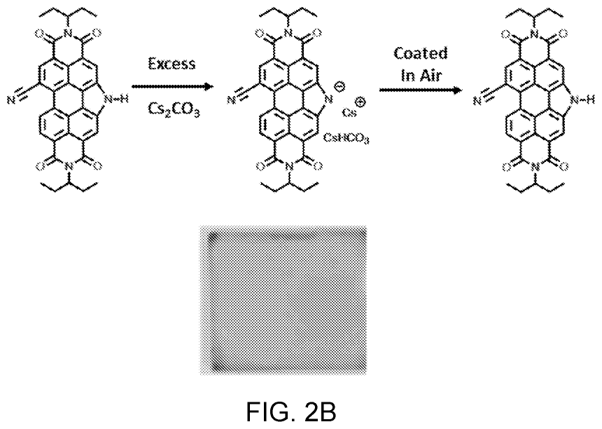

The solubility of different salts in a selected solvent can be generally assessed by adding a measured amount of the salt to the solvent, sonicating the mixture for a selected time and visually observing if a clear solution is formed. The solubilities of Li₂CO₃, Na₂CO₃, K₂CO₃, and Cs₂CO₃ in n-propanol (PrOH) were assessed by adding 10 mg/mL of the salt to n-propanol and sonicating the mixture for 1 hour. A clear solution was observed only with Cs₂CO₃, and this base was selected for preparation of inks for PDIN-H film formation. FIG. 2A illustrates deprotonation of PDIN-H (compound 1) with Cs₂CO₃ (CC) enabling alcohol-soluble solutions, where the pyrrolic N—H bond can be deprotonated to yield an ionic molecule soluble in polar solvents (i.e., PrOH as illustrated). Cs₂CO₃ is shown added in molar excess with respect to the N-annulated PDI. Upon the addition of Cs₂CO₃, a color change from orange (PDIN-H suspension in PrOH) to purple (soluble dye) is observed. In this process, Cs₂CO₃ deprotonates PDIN-H creating an alcohol soluble ionic dye, PDIN⁻Cs⁺. Spin coating of the alcohol-soluble ionic dye on a PET substrate in air results in the formation of a uniform solvent-resistant thin film, as shown in FIG. 2A, due to spontaneous protonation after solvent removal. The film shown in FIG. 2A is formed from a PrOH solution containing 10 mg/ml of PDIN-H and 2 molar equivalents of Cs₂CO₃ with respect to PDIN-H and exhibits a red color. FIG. 2B illustrates the analogous process for film formation from CN-PDIN-H (compound 2).

The film shown in FIG. 2B is formed by spin coating of a PrOH solution containing 10 mg/ml of CN-PDIN-H and 2 molar equivalents of Cs₂CO₃ with respect to CN-PDIN-H on a PET substrate and also exhibits a red color.

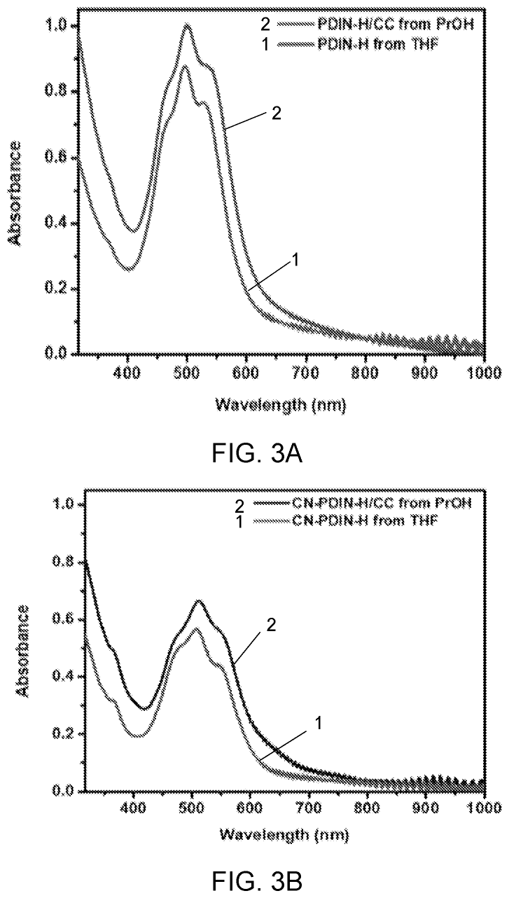

FIG. 3A shows the optical absorption spectra of a PDIN-H film spin coated from tetrahydrofuran (THF) (1) (containing 10 mg/mL PDIN-H) compared to that of a film spin coated from PrOH (2) containing (10 mg/mL PDIN-H). FIG. 3B shows the optical absorption spectra of a CN-PDIN-H film spin coated from tetrahydrofuran (THF) (1) (containing 10 mg/mL CN-PDIN-H) compared to that of a film spin coated from PrOH (2) containing (10 mg/mL CN-PDIN-H). Films spun from THF solution did not contain any base. Films spun from PrOH contained 2 molar equivalents of CC.

The optical absorption spectrum of the PDIN-H film is nearly identical to that of the PDIN-H/CC film. Both films exhibited absorption from 400 nm to 650 nm with λₘₐₓ at ˜500 nm, a weak shoulder at 466 nm and a low energy shoulder at 530 nm which is consistent with what has been previously reported in PDI-based thin films. [Harding et al., 2020]. With respect to the CN-PDIN-H and CN-PDIN-H/CC films spin coated from THF and PrOH, both films exhibit similar profiles with Amax at 510 nm, a weak shoulder at 470 nm and a low energy shoulder at 550 nm. A slight red shift in all the peaks of CN-PDIN-H films compared to PDIN-H is observed, consistent with the solution optical absorption. This red shift is due to the addition of the electron withdrawing cyano group that increases electron affinity, lowering the LUMO energy level, and thus narrowing the optical gap. [Martell et al., 2021] The similar optical absorbance profiles of thin films spin coated from THF, or PrOH with CC provides evidence of the protonation of both PDIN-H and CN-PDIN-H in air rendering the final films as a mixture of PDIN-H or CN-PDIN-H with embedded CC. No anionic PDI was observed in the films and CC does not alter the optical properties of either PDIN-H or CN-PDIN-H.

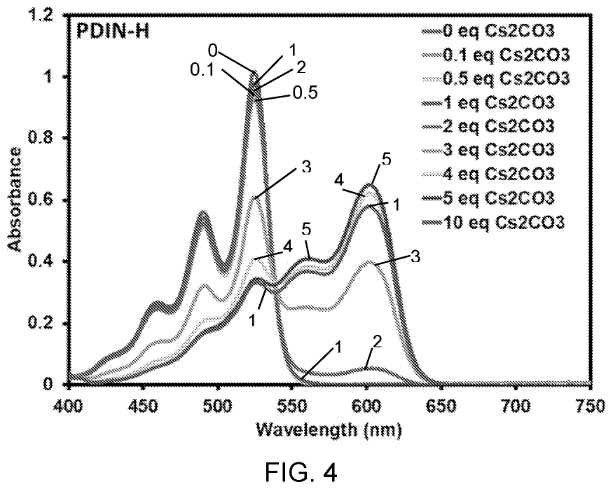

FIG. 4 illustrates the effect of adding different Cs₂CO₃ molar equivalents on the deportation (color change) of PDIN-H in PrOH. With PDIN-H concentration of 0.05 mg/mL, a gradual change in color from yellow/orange to purple was observed with addition of increasing Cs₂CO₃ equivalents (0-10 equivalents). In PrOH containing 0.5 eq. Cs₂CO₃, no change in the PDIN-H absorption profile is observed with the same characteristic PDI peaks at 459, 490, and 525 nm. For PDIN-H deprotonation begins to appear at about 1 equivalent CC. At 2 eq. Cs₂CO₃, a small lower energy peak appears at 600 nm which is attributed to the PDIN⁻ anion. [Harding et al., 2020; Vespa et al., Eur. J. Org. Chem. 2018, 2018, 4592.] At 10 eq. Cs₂CO₃ it appears that the PDIN-H is fully deprotonated with absorption profile of PDIN⁻ anion only which has previously been observed in other PDI-based molecules. [Wen et al., Angew. Chem. Int. Ed. 2019, 58, 13051.] A similar experiment was performed [results not shown] with CN-PDIN-H (0.05 mg/mL in PrOH) with a change in color from deeper orange to deeper purple as Cs₂CO₃ molar equivalents (0 to 10) were added. For CN-PDIN-H deprotonation begins to appear at about 0.5 equivalent CC. The addition of the cyano moiety renders the perylene diimide core more electron deficient and results in the pyrrolic H becoming more acidic.

The chemical structures of the photoactive materials (i.e., polymer donors and acceptors) used as BHJ in the OPV devices fabrication are shown in Scheme 3.

PDIN-H/Cs₂CO₃ was used as the ETL in a conventional OPV device architecture as shown in FIG. 1A. PEDOT:PSS was used as the hole transport layer (HTL). The top metal electrode was Ag. The benchmark high efficiency non-fullerene-based PM6:Y6 BHJ and the fullerene-based PBDB-T:PC₆₁EM BHJ were used to evaluate the newly developed ETL performance.

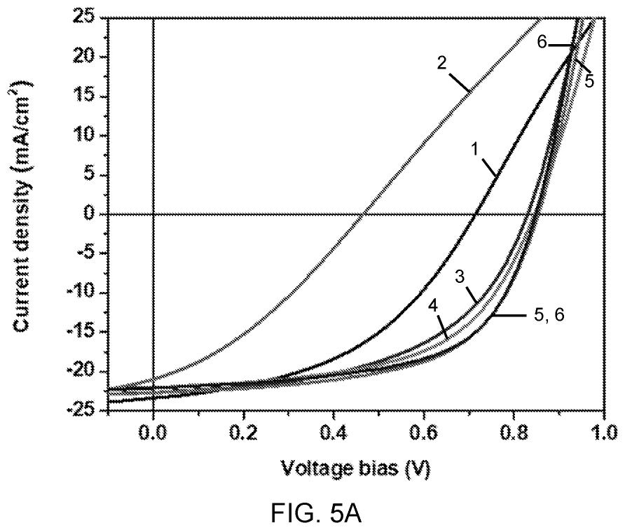

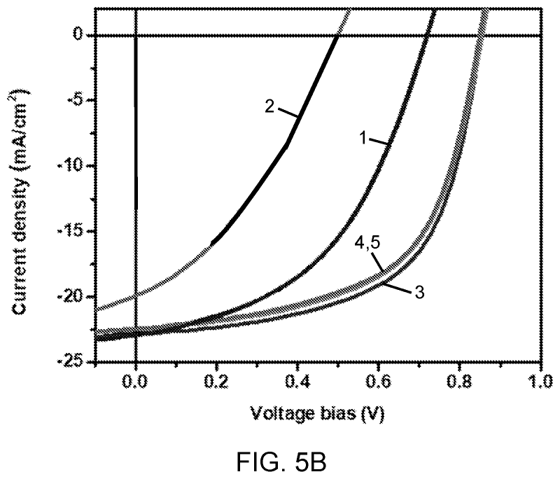

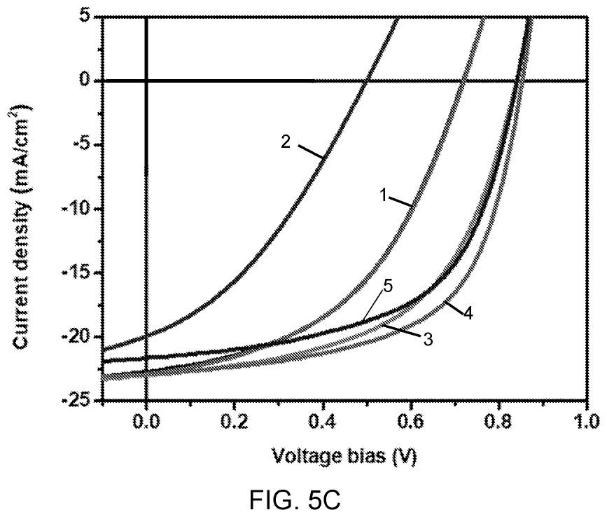

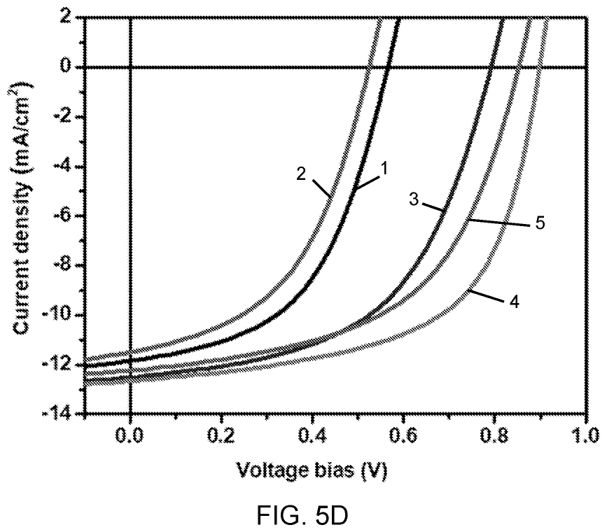

PDIN-H/CC performance as an efficient ETL was evaluated in OPV devices employing two different BHJ active layers; PM6:Y6 and PBDB-T:PC₆₁BM. Current density-voltage (J-V) curves of the OPV devices and their corresponding photovoltaics characteristics are shown in FIGS. 5A-5D and Table 1, respectively. A series of devices based on air processed PM6:Y6 BHJ active layers was fabricated with different ETL conditions for comparison (FIGS. 5A-5C). Control devices without interlayer (Ag-only), with PrOH-only, and with Cs₂CO₃ dissolved in PrOH were fabricated to compare with devices employing PDIN-H/Cs₂CO₃ under various conditions as ETL (Table 1). Devices without ETL (Ag-only) achieved PCE=7.8% (J_{sc}=22.6 mA/cm², V_{oc}=0.72 V, and FF=48%) similar to devices with PrOH-only (PCE=7.9%, J_{sc}=22.8 mA/cm², V_{oc}=0.72 V, and FF=48%). These results confirm that the PrOH as a solvent does not have any role in the electron transport properties of the ETL. Using 2 molar eq. Cs₂CO₃ only dissolved in PrOH as ETL impacted the devices negatively and caused a significant drop in all photovoltaics parameters (PCE=3.5%, J_{sc}=19.8 mA/cm², V_{oc}=0.50 V, and FF=35%). The poor performance of solution processed Cs₂CO₃ as ETL with the high WF Ag metal electrode was previously confirmed by Huang et al., 2007.

Using PDIN-H/Cs₂CO₃ showed significant improvement mainly in open-circuit voltage (V_{oc}) and fill factor (FF) which is an indication of the ability of the new ETL to tune the energy level at the Ag electrode/BHJ active layer interface. [Yip et al., Energy Environ. Sci. 2012, 5, 5994.]

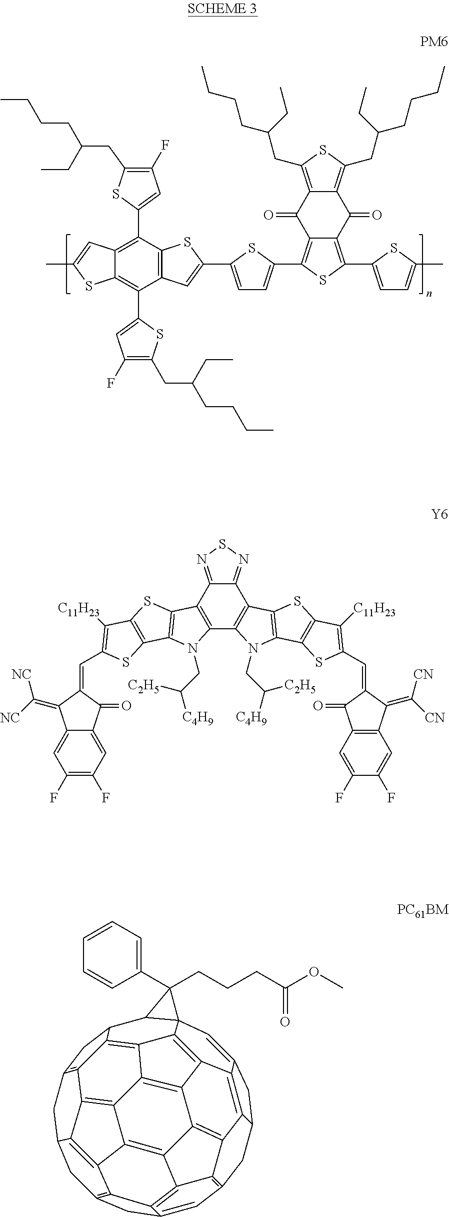

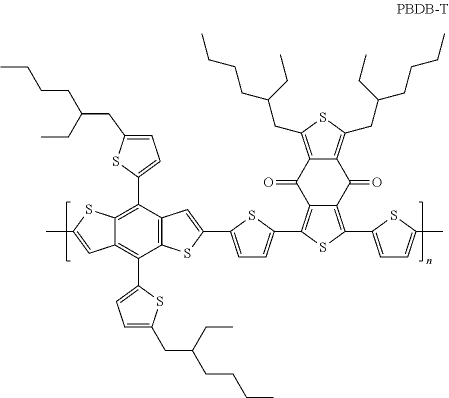

PDIN-H/CC processed under various spin coating speeds showed the best performance at 5000-6000 rpm with PCE=11.4% (J_{sc}=22.6 mA/cm², V_{oc}=0.85 V, and FF=59%). With further optimization of the PDIN-H/Cs₂CO₃ processing, a POE of 11.8% (J_{sc}=22.8 mA/cm², V_{oc}=0.85 V, and FF=61%) was achieved. Different PDIN-H concentrations (0.5, 1.0, 1.5 mg/mL) spin coated at 6000 rpm showed PCEs>11% with 0.5 mg/mL as the optimized concentration. 2 molar eq. Cs₂CO₃ was found to be the optimized molar ratio. Expanding the application of the new ETL to a fullerene-based photoactive system (FIG. 50) showed promising results and confirmed its functionality.

TABLE 1
Photovoltaics characteristics of PM6:Y6 and PBDB-T:PC₆₁BM
BHJs with PDIN-H/CC ETL under various processing conditions

| | | | | |
|---|---|---|---|---|
| | V_{oc} | J_{sc} | FF | PCE |
| Condition | (V) | (mA/cm²) | (%) | (%) |

Control Devices (PM6:Y6)

| | | | | |
|---|---|---|---|---|
| Ag (wo ETL) | 0.72 | 22.6 | 48 | 7.8 |
| PrOH-only | 0.72 | 22.8 | 48 | 7.9 |
| 2 eq. Cs₂CO₃ (CC) only | 0.50 | 19.8 | 35 | 3.5 |

PDIN-H/CC with Different Spin Speeds (PM6:Y6)

| | | | | |
|---|---|---|---|---|
| 0.5 mg/ml PDIN-H/2 eq. CC | 0.83 | 22.6 | 52 | 9.8 |
| (3K) | | | | |
| 0.5 mg/ml PDIN-H/2 eq. CC | 0.84 | 22.0 | 56 | 10.5 |
| (4K) | | | | |
| 0.5 mg/ml PDIN-H/2 eq. CC | 0.85 | 22.6 | 59 | 11.4 |
| (5K) | | | | |
| 0.5 mg/ml PDIN-H/2 eq. CC | 0.85 | 22.0 | 60 | 11.3 |
| (6K) | | | | |

PDIN-H/CC with Different PDIN-H Concentrations (PM6:Y6)

| | | | | |
|---|---|---|---|---|
| 0.5 mg/ml PDIN-H/2 eq. CC | 0.85 | 22.8 | 61 | 11.8 |
| (6K) | | | | |
| 1.0 mg/ml PDIN-H/1 eq. CC | 0.85 | 22.4 | 59 | 11.3 |
| (6K) | | | | |
| 1.5 mg/ml PDIN-H/1 eq. CC | 0.85 | 22.3 | 59 | 11.2 |
| (6K) | | | | |

PDIN-H/CC with Different Cs₂CO₃ (CC) Molar Ratios (PM6:Y6)

| | | | | |
|---|---|---|---|---|
| 0.5 mg/ml PDIN-H/1 eq. CC | 0.84 | 23.0 | 55 | 10.6 |
| (6K) | | | | |
| 0.5 mg/ml PDIN-H/2 eq. CC | 0.85 | 22.8 | 61 | 11.8 |
| (6K) | | | | |
| 0.5 mg/ml PDIN-H/3 eq. CC | 0.84 | 21.6 | 58 | 10.5 |
| (6K) | | | | |

Control Devices (PBDB-T:PC₆₁BM)

| | | | | |
|---|---|---|---|---|
| Ag (wo ETL) | 0.54 | 11.3 | 50 | 3.2 |
| PrOH-only | 0.52 | 11.4 | 49 | 2.9 |
| 2 eq. Cs₂CO₃ (CC) only | 0.79 | 12.4 | 54 | 5.3 |

PDIN-H/CC with Different Spin Speeds (PBDB-T:PC₆₁BM)

| | | | | |
|---|---|---|---|---|
| 0.5 mg/ml PDIN-H/2 eq. CC | 0.90 | 12.6 | 60 | 6.8 |
| (4K) | | | | |
| 0.5 mg/ml PDIN-H/2 eq. CC | 0.85 | 12.2 | 54 | 5.7 |
| (6K) | | | | |

The optimized conditions (0.5 mg/mL and 2 eq. Cs₂CO₃) were applied as ETL with PBDB-T:PC₆₁BM BHJ active layer. OPV devices with PCE=6.8% (J_{sc}=12.6 mA/cm², V_{oc}=0.90 V, and FF=60%) compared to PCE=3.2% (J_{sc}=11.4 mA/cm², V_{oc}=0.54 V, and FF=50%) for devices without ETL (Ag-only) were reached. Collectively, the results confirm the application of PDIN-H/CC as ETL in OPVs. Further characterizations will provide more detail on the role of PDIN-H/CC in energy level alignment at the Ag electrode/BHJ active layer interface and their working mechanism.

### Materials and Solutions Preparation

Polymer donors (PM6 and PBDB-T) and Y6 NFA were purchased from Brilliant Matters. PC₆₁BM fullerene acceptor was purchased from Nano C. PDIN-H was synthesized and purified following previous work. [Hendsbee et al., Chem. Mater. 2016, 28, 7098.] Clevios PVP AI 4083 PEDOT:PSS was purchased from Heraeus. The PM6:Y6 BHJ (1:1.2 w/w and total concentration of 16 mg/mL) was dissolved in chloroform with 0.5% (v/v) chloronaphthalene (CN) as solvent additive. PBDB-T:PC₆₁BM (1:1.25 and 18 mg/mL total concentration) was dissolved in chlorobenzene. All solutions were heated at 70° C. with continuous stirring in air for at least 4 hours prior to active layer spin coating. 10 mg/mL Cs₂CO₃ was dissolved in 1-propanol (PrOH) via ultrasonication for 1 hour until the solution was transparent. Solutions with different Cs₂CO₃ molar equivalents and PDIN-H concentrations were prepared using PrOH as a solvent.

### OPV Devices Fabrication

Conventional device architecture [glass/ITO/PEDOT:PSS/BHJ/PDIN-H/Ag] was used for device fabrication (FIG. 1A). ITO-patterned substrates were cleaned by sequentially ultrasonicating with detergent and deionized water, acetone, and isopropanol followed by UV/ozone cleaning for 30 min. PEDOT:PSS was spin coated at 4000 rpm (4K) for 60 seconds and then annealed at 140° C. for 20 min in air. PM6:Y6 active layers were spin coated at 3500 rpm (3.5K) for 30 seconds and annealed at 110° C. for 10 min. PBDB-T:PC₆₁BM active layers were spin coated at 1400 rpm for 60 seconds. PDIN-H films were spin coated on the active layers at different spin speeds as indicated (ranging from 3,000 rpm-6,000 rpm) for 30 seconds. All films were coated in air except that the 100 nm Ag electrode was thermally evaporated under vacuum (1×10⁻⁵ Torr). The photoactive areas of the OPV devices were defined by a shadow mask to be 0.14 cm².

### Characterization

UV-Visible Spectroscopy (UV-Vis): Measurements were recorded using an Agilent Technologies Cary 60 UV-Vis spectrometer at room temperature. All solution UV-Vis experiments were run using 10 mm quartz cuvettes. The current density-voltage (J-V) curves were measured by a Keithley 2420 source measure unit. The photocurrent was measured under AM 1.5 illumination at 100 mW/cm² (Newport 92251A-1000 Solar Simulator). The standard silicon solar cell (Newport 91150V) was used to calibrate light intensity. Slot-die coated films were coated using a compact sheet coater from FOM Technologies equipped with a 13 mm wide slot-die head using a solution dispense rate (pump rate) of 200 μL/min and a substrate motion speed of 300 mm/min.

### Example 2: The Effect of Different Molar Equivalents of Cs₂CO₃ on OPV Device Performance

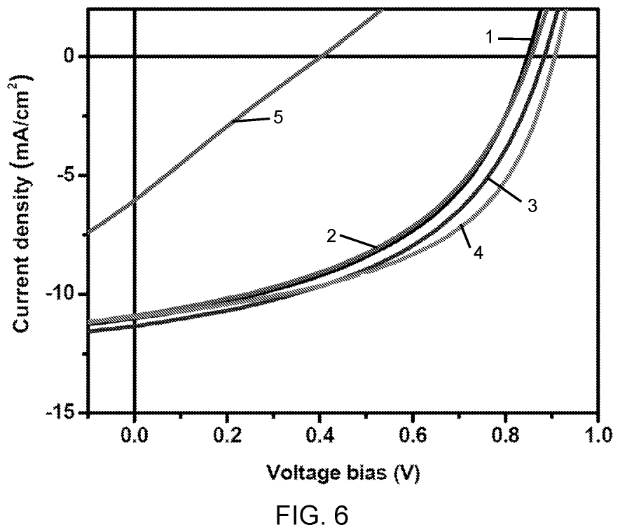

FIG. 6 illustrates J-V curves of an OPV device with PBDB-T:PC₆₁BM photoactive layer with spin coated PDIN-H/Cs₂CO₃ (0.5 mg/mL PDIN-H) in PrOH with various Cs₂CO₃ molar equivalents added. Data are provided in Table 2. This is an early state experiment to assess the effect of the relative amounts of PDIN-H and Cs₂CO₃. As shown in Table 1, higher PCE can be obtained using the same system.

TABLE 2
Effect of Equivalents of Cs₂CO₃ on OPV Device Performance

| | | | | |
|---|---|---|---|---|
| Condition | V_{oc} (V) | J_{sc} (mA/cm²) | FF (%) | PCE (%) |

PDIN-H/CC with Different molar equivalent (PBDB-T:PC₆₁BM)

| | | | | |
|---|---|---|---|---|
| 2 eq. Cs₂CO₃ | 0.85 | 10.86 | 46 | 4.3 |
| 3 eq. Cs₂CO₃ | 0.88 | 11.3 | 48 | 4.8 |
| 4 eq. Cs₂CO₃ | 0.90 | 10.9 | 51 | 5.1 |
| 5 eq. Cs₂CO₃ | 0.40 | 6.1 | 24 | 0.6 |

### Example 3: Spin-Coating Solutions Employing Ethanol and Mixtures of 1-Propanol with Other Alcohols

Uneven drying of slot-die coated films of PDIN-N/Cs₂CO₃ (2 eq. in 1-propanol) on spin-coated films of PBDB-T:PC₆₁BM was observed. 1-Propanol is a relatively high boiling point alcohol (97° C.). It was considered that the use of 1-propanol as the solvent caused the uneven PDINH/CC film drying during slot-die coating. The solubility of Cs₂CO₃ in different alcohols was assessed by visual observation of mixtures of 10 mg/mL of Cs₂CO₃ in ethanol, 1-propanol, isopropyl alcohol and 1-butanol. Cs₂CO₃ was found to be soluble in ethanol and 1-propanol (PrOH, herein) at least at 10 mg/mL.

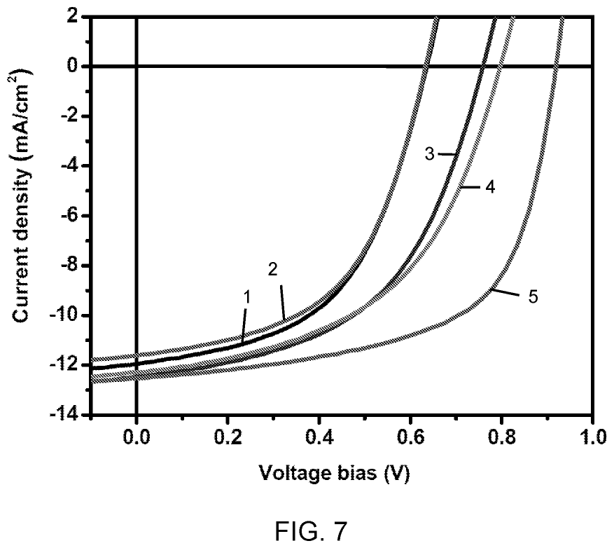

Spin coating of PDIN-H/Cs₂CO₃ solutions in ethanol was assessed. FIG. 7 illustrates J-V curves for an active layer of PBDB-T:PC₆₁EM with spin coated PDIN-H/Cs₂CO₃.

The curves include conventional geometry devices with no ETL (Ag, control) and ethanol only (control) compared with PDIN-H/1 eq. Cs₂CO₃ and PDIN-H/2 eq. Cs₂CO₃ in ethanol and PDIN-H/2 eq Cs₂CO₃ in 1-propanol. Performance data is provided in Table 3.

TABLE 3
Performance Data for OPV PBDB-T:PC₆₁BM devices with
spin coated PDIN-H/Cs₂CO₃ in ethanol or 1-propanol.

| | | | | |
|---|---|---|---|---|
| Condition | V_{oc} (V) | J_{sc} (mA/cm²) | FF (%) | PCE (%) |

PDIN-H/CC in EtOH vs 1-propanol (PBDB-T:PC₆₁BM)

| | | | | |
|---|---|---|---|---|
| Ag (wo ETL) | 0.64 | 11.9 | 53 | 4.0 |
| EtOH-only | 0.63 | 11.6 | 53 | 3.9 |
| 0.5 mg/ml PDINH/1 eq. CC | 0.76 | 12.4 | 52 | 4.9 |
| (EtOH) | | | | |
| 0.5 mg/ml PDINH/2 eq. CC | 0.80 | 12.2 | 51 | 5.0 |
| (EtOH) | | | | |
| 0.5 mg/ml PDINH/2 eq. CC | 0.92 | 12.5 | 62 | 7.1 |
| (PrOH) | | | | |

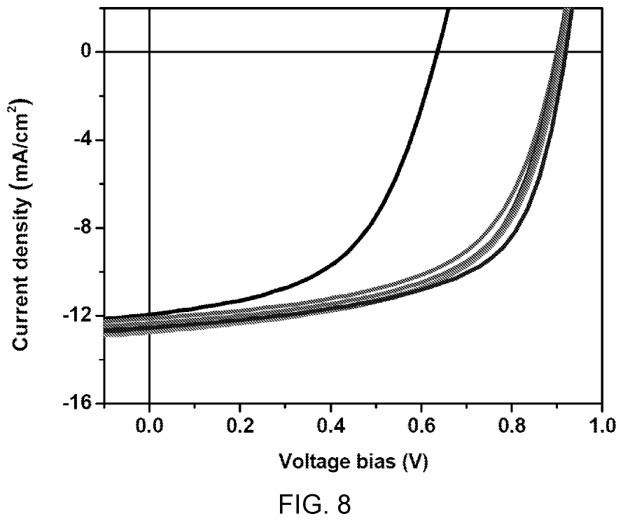

1-PrOH with PCE>7% surpasses EtOH (PCE of 5%) for spin coated PDINH/Cs₂CO₃. Selected mixtures of different alcohols were then used to prepare 0.5 mg/mL PDINH/2 eq. Cs₂CO₃ solutions. FIG. 8 illustrates J-V curves of conventional OPV devices with PBDB-T:PC₆₁BM active layers and with ETL spin coated from PDIN-H/Cs₂CO₃ solutions in certain alcohol mixtures with 1-propanol. The curves include conventional geometry devices with no ETL (Ag, control) and 1-propanol only (control) compared with PDIN-H/2 eq. Cs₂CO₃ processed from mixtures of 1-propanol with ethanol or isopropyl alcohol. Performance data is provided in Table 4.

TABLE 4
Performance Data for OPV PBDB-T:PC₆₁BM devices
with spin coated PDIN-H/CC in Alcohol mixtures.

| | | | | |
|---|---|---|---|---|
| Condition | V_{oc} (V) | J_{sc} (mA/cm²) | FF (%) | PCE (%) |

PDIN-H/CC in EtOH vs 1-propanol (PBDB-T:PC₆₁BM)

| | | | | |
|---|---|---|---|---|
| Ag (wo ETL) | 0.64 | 11.9 | 53 | 4.0 |
| PrOH | 0.92 | 12.5 | 62 | 7.1 |
| PrOH:EtOH (3:1) | 0.90 | 12.1 | 58 | 6.4 |
| PrOH:EtOH (1:1) | 0.90 | 12.6 | 60 | 6.8 |
| PrOH:IPA (3:1) | 0.91 | 12.7 | 59 | 6.8 |
| PrOH:IPA (1:1) | 0.90 | 12.3 | 60 | 6.7 |

The 1-propanol solvent mixtures with other alcohols achieve comparable performance to use of 1-propanol alone as the solvent.

### Example 4: Photovoltaic Parameters of Additional OPV Device with PDIN-H or CN-PDIN-H/Cs₂CO₃ Interlayers

Conventional OPV devices with PM6:Y6 active layers were constructed analogously to those described above. Device architecture was glass/ITO/PEDOT:PSS/PM6:Y6/interlayer/Ag. Devices were prepared with PDIN-H/CC (compound 1) or CN-PDIN-H/CC (compound 2) with interlayers spin-coated from PrOH solutions containing 0.25 mg/mL of PDIN-H or CN-PDIN-H and 2 molar equivalents of CC. Control devices with no interlayer (i.e., Ag-only on top of the photoactive layer) were also prepared. Complete device metrics are presented in Table 5.

TABLE 5
Photovoltaic parameters of PM6:Y6 devices with and without
PDIN-H/CC or CN-PDIN-H/CC interlayers spin coated from PrOH.
All OPV devices were fabricated and tested in air.

| glass/ITO/ | | | | | |
|---|---|---|---|---|---|
| PEDOT:PSS/PM6:Y6/ | V_{oc} | J_{sc} | J_{sc}^{Cal} | FF | PCE |
| interlayer/Ag | (V)^{(a)} | (mA/cm²)^{(a)} | (mA/cm²) | (%)^{(a)} | (%)^{(a)} |
| No interlayer (Ag-only) | 0.78 | 23.49 | 22.6 | 51 | 9.3 |
| | (0.75) | (22.5) | | (52) | (8.7) |
| PDIN-H/CC ^{(b)} | 0.85 | 22.8 | 22.2 | 61 | 11.8 |
| | (0.85) | (22.4) | | (59) | (11.2) |
| CN-PDIN-H/CC ^{(b)} | 0.85 | 22.7 | 21.9 | 63 | 12.2 |
| | (0.86) | (22.0) | | (63) | (11.8) |

^{(a)}The values of the best device are reported, while the values in the parentheses are the average PCEs from over 15 devices with 0.14 cm² active area.
^{(b)} 2 molar equivalents of CC used. Interlayer films were spin-coated from 0.25 mg/mL PDI in PrOH at 6000 rpm.

PM6:Y6 OPV devices without an interlayer had modest PCE on average of 8.7%. Incorporation of the PDIN-H/CC interlayer boosted the PCE to an average of 11.2%. Using the CN-PDIN-H interlayer boosted the PCE to an average of 11.8%. Best device performance was found with the interlayers processed at a concentration of 0.25 mg/mL PDI in PrOH with 2 molar equivalents of CC added. Using PDIN-H/CC or CN-PDIN-H/CC as interlayers enhanced the device performance by 29% (from 8.7 to 11.2%) and 36% (from 8.7 to 11.8%), respectively. Comparatively, a recent study reported a PDINN interlayer to enhance OPV device performance by 25% from 13.8% (Ag-only) to 17.2% (with PDINN interlayer) [Yao et al., 2020]. This comparison highlights that similar performance increases are observed with devices herein that were fabricated and tested in air, with PDINN devices that were fabricated and tested under controlled environment (dry nitrogen or argon with extremely low levels of water and oxygen<1 ppm).

PCE increases observed are a result of improved V_{oc} and FF. The J_{sc} remained largely unchanged. The calculated integrated J_{sc}^{Cal} values from measured EQE spectra (not shown) match with the experimental J_{sc} values obtained from J-V curves. Optical absorption spectra of photoactive layers without and with the PDI based interlayers are nearly identical which indicates the PM6:Y6 film remains intact after interlayer processing. OPV devices without an interlayer, but with the PM6:Y6 photoactive layer having been treated with a PrOH wash have equivalent average PCE of 8.7%. A PrOH wash had little impact on the surface roughness of the PM6:Y6 film (as assessed by AFM height images, not shown).

To further validate the OPV device performance in terms of state-of-the-art the standard PFN-Br interlayer was used in an analogous OPV device for comparison. Average device PCEs were 12%, with a highest PCE of 12.8%. The results using the PFN-Br interlayer are similar to the devices described herein using the PDI-H interlayers with CC and confirms the new ink formulation provided herein are viable for delivering useful conventional-type OPV devices.

### Example 5: Slot-Dye Coating of PDIN-H/CC and Cn-PDIN-H/CC Interlayers

PDI/CC interlayer inks were utilized for slot-die coating, a roll-to-roll compatible method, for film formation. During the initial slot-die coating experiments using PDIN-H/CC and CN-PDIN-H/CC interlayer films from PrOH, a drying issue was observed that yielded low-quality films. The lower quality of such films was attributed to the longer film drying times associated with slot-die coating, relative to spin coating. It is believed that the use of the protic and hydrophilic PrOH solvent on a hydrophobic surface (PM6:Y6) resulted in pooling and blotchy films.

Ethyl acetate (EA), an aprotic polar solvent, was identified as a suitable solvent to enable uniform film formation of PDIN-H/CC and CN-PDIN-H/CC interlayers via slot-die coating. This alternative non-toxic, green solvent was found to dissolve the PDIN-H/CC and CN-PDIN-H/CC material combinations and to be immiscible with the photoactive layer. However, Cs₂CO₃ itself was found not to be sufficiently soluble in EA to allow preparation of inks containing high enough levels of CC such that 2 eq of the base with respect to the desirable amount of PDIN-H compound could be added and dissolve.

Use of a solvent mixture of EA (or an appropriate solvent for film formation) and an alcohol (e.g., PrOH) in which CC is very soluble was investigated. In particular, a method for preparation of the PDIN-H ink was devised in which a more concentrated solution of CC (e.g., 10 mg/mL) in an alcohol (e.g., PrOH) was prepared. Then an appropriate volume of the solution of the CC base in the alcohol was added to the film formation solvent (e.g., EA) to achieve the desired amount of the CC base in the solvent mixture. The solvent mixture containing dissolved CC was then combined with the selected amount of the PDIN-H compound resulting in the film forming ink containing the selected amount of the PDIN-H compound and the desired number of equivalents of CC with respect to the PDIN-H compound. Details of this method for preparing PDIN-H inks are described below exemplified for PDIN-H/CC and CN-PDIN-H/CC inks in a mixture of EA and PrOH.

An EA:PrOH solvent system (1.00:0.06) was used to form stable PDIN-H/CC and CN-PDIN-H/CC inks for coating. The minor amount of PrOH was employed to ensure complete dissolution of CC. PDIN-H/CC and CN-PDIN-H/CC films slot-die coated from EA:PrOH inks were uniform with a dramatic improvement in the film quality compared to films slot-die coated from PrOH only. The improved film formation is believed a result of the increased wettability of EA on the PM6:Y6 photoactive layers compared to PrOH, as demonstrated by contact angle measurements (10° for EA and 16° for PrOH). The higher vapor pressure of EA compared to PrOH is also believed to contribute to the improved film formation by increasing the drying rate.

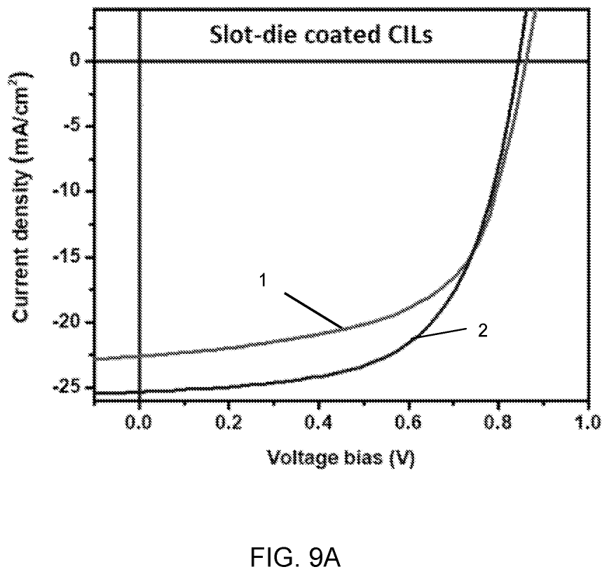

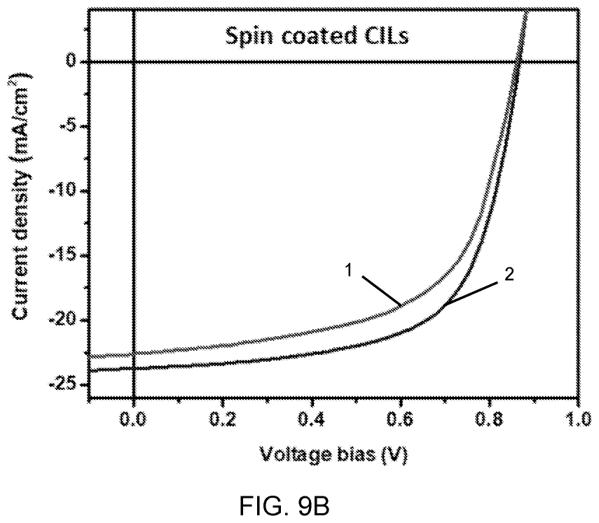

OPV devices with PDIN-H/CC or CN-PDIN-H/CC interlayers slot-die coated from EA:PrOH had performance comparable to devices with spin-coated interlayers (FIG. 9 and Table 6).

TABLE 6
Photovoltaic parameters of OPV PM6:Y6 devices with PDIN-H/CC or CN-PDIN-
H/CC interlayers spin coated or slot-die coated from EA/PrOH (1.0:0.06
v/v) solutions. All OPV devices were fabricated and tested in air.

| | | | | | |
|---|---|---|---|---|---|
| | | J_{sc} | J_{sc}^{Cal} | | |
| Condition ^{(a)} | V_{oc} (V)^{(b)} | (mA/cm²)^{(b)} | (mA/cm²) | FF (%)^{(b)} | PCE (%)^{(b)} |

Slot-die coated interlayers

| | | | | | |
|---|---|---|---|---|---|
| PDIN-H/CC^{(c)} | 0.85 (0.84) | 23.6 (23.4) | 23.1 | 59 (55) | 11.8 (10.9) |
| CN-PDIN-H/CC^{(c)} | 0.84 (0.84) | 25.3 (24.7) | 24.4 | 61 (60) | 13.1 (12.5) |

Spin coated interlayers

| | | | | | |
|---|---|---|---|---|---|
| PDIN-H/CC^{(d)} | 0.86 (0.86) | 22.5 (22.0) | 22.1 | 60 (59) | 11.7 (11.1) |
| CN-PDIN-H/CC^{(d)} | 0.87 (0.86) | 23.7 (23.2) | 23.2 | 65 (62) | 13.2 (12.4) |

^{(a)} Device architecture = glass/ITO/PEDOT:PSS/PM6:Y6/CIL interlayer/Ag
^{(b)}The values of the best device are reported, while the values in the parentheses are the average PCEs from over 15 devices with 0.14 cm² active area.
^{(c)}2 molar equivalents of CC used. PDIN-H/CC and CN-PDIN-H were slot-die from EA:PrOH (1.00:0.06 v/v) solutions (0.5 mg/mL).
^{(d)}2 molar equivalents of CC used. PDIN-H/CC and CN-PDIN-H/CC were spin coated from EA:PrOH (1.00:0.06 v/v) solutions (0.5 mg/mL) at 6000 rpm.

Average device PCEs with slot-die coated PDIN-H/CC and CN-PDIN-H/CC interlayers were 10.9% and 12.5%, respectively. The J_{sc} were confirmed and by calculating the integrated J_{sc}^{Cal} from EQE spectra (not shown). Analysis of the photoactive layer films before and after both EA/PrOH washing reveals minimal changes in both surface roughness and light absorption indicating the PM6:Y6 photoactive layer can withstand EA solvent. Analysis of the devices with interlayers reveals a smoothing of the surface with the PDIN-H/CC layer and a slight roughening of the surface with the CN-PDI-NH/CC layer. Devices with CN-PDIN-H/CC interlayers have slightly better PCE, suggesting that a rougher surface is beneficial to the device operation. Overall, the OPV device performance with spin-coated or slot-die coated interlayers is similar and demonstrates that the PDI ink formulation herein are viable for use in large area OPV construction.

### Materials

Polymer donor (PM6) and non-fullerene acceptor (Y6) were purchased from Brilliant Matters. Both PDIN-H and CN-PDIN-H were synthesized and purified as described previously. [Harding et al., 2020] Clevios PVP Al 4083 PEDOT:PSS was purchased from Heraeus. Cesium carbonate (CC) was purchased from Sigma Aldrich. All solvents were purchased from Sigma Aldrich and used as received.

### Photoactive Layer Solution Preparation

The PM6:Y6 active layer (1:1.2 w/w and total concentration of 16 mg/mL) was dissolved in chloroform with 0.5% (v/v) chloronaphthalene (CN) as solvent additive. All solutions were heated at 60° C. with continuous stirring in air for at least 4 hours prior to active layer spin coating.

### Interlayer Ink Preparation

The following are exemplary steps to prepare different concentrations of PDI/CC ink used in spin coating or slot-die coating. Taking 0.5 mg/mL PDIN-H (or CN-PDIN-H)/2 molar equivalent CC as an example for the preparation:

### Preparation of the Basic Alcohol Solution (CC in PrOH)

Weigh out 10 mg CC in a vial and add 1 mL of PrOH to it. Wrap with parafilm to ensure sealed lid and sonicate for ˜ 90 minutes until CC is fully dissolved (i.e., giving a transparent solution).

Determine the moles of CC needed from specific mass of PDIN-H or CN-PDIN-H (0.5 mg/mL) for 2 CC molar equivalents:

$$( 0.5 mg / 1000 mg / g ) \div ( 543.62 g / mol PDIN - H ) = 9.1976 \times {10}^{- 7} mol PDIN - H$$

$$( 9.1976 \times {10}^{- 7} mol PDIN - H \times 2 mol CC ) \div ( 1 mol PDIN - H ) = 1.8395 \times {10}^{- 6} mol CC$$

Molecular weight (g/mol) of CC=325.82 g/mol, of PDIN-H=543.62 g/mol, and of CN-PDIN-H=568.63 g/mol.
Determine the concentration of CC needed in 1 mL solvent (for 2 eq CC with respect to PDIN-H)
1.83952×10⁻⁶ mol CC×(325.82 g)/mol×1000=0.59935 mg CC needed total in 1 mL=0.59935 mg/mL
Determine dilution needed from the prepared 10 mg/mL CC basic alcohol solution using C₁V₁=C₂V₂
10 mg/mL CC×V₁=0.59935 mg/mL×1.1 mL (slight excess of total volume needed) V₁=0.06592877 mL from 10 mg/mL CC basic alcohol solution

0.06592877 mL (rounded to 0.0659 mL) of 10 mg/mL CC basic alcohol solution should be added to the difference of total volume (1.1 mL-0.0659 mL=1.0341 mL) of pure solvent (PrOH or EA). For the PDIN-H 0.5 mg/mL solution with 2 molar eq of CC, 0.0659 ml of the CC basic alcohol solution is added to 1.0341 mL of pure solvent. Either PrOH or EA.

The volume of CC basic alcohol solution (e.g., 10 mg/mL CC in PrOH) is adjusted dependent upon the molecular weight of the PDIN-H compound employed and the desired number of eq of base in the ink solution.

### Preparation of PDIN-H/CC or CN-PDIN-H

After adding 0.0659 mL of 10 mg/mL CC basic alcohol solution to 1.0341 mL of pure solvent (PrOH or EA) for making the PDIN-H ink, the mixed solvent with CC is put on a shaker for 5 minutes. Then 1 mL of the mixed solvent with CC is added to a vial containing the preweighed PDIN-H. The vial is then sealed and placed on shaker for 60 minutes for PDIN-H. CN-PDIN-H inks are prepared analogously by adjusting the volume of CC basic alcohol solution added to pure solvent (0.0630 mL of CC basic alcohol solution is added to 1.0370 mL of pure solvent). PDIN-H/CC ink is light purple in color and CN-PDIN-H ink is dark purple in color. To prepare inks with varied PDIN-H compound concentrations or varied CC molar equivalents, the previous steps can be followed by readily adapting weights of components and volumes of solvents to obtain the desired concentrations or molar equivalents.

It will be appreciated by those of ordinary skill in the art that PDIN-H inks having desired amounts of PDIN-H compound and desired numbers of equivalents of CC base can be prepared using CC basic alcohol solutions with concentrations of CC other than 10 mg/mL by adjusting the amount of CC and the volume of solvent added. It will be appreciated that solvents other than PrOH (e.g., EtOH, mixtures of alcohols, among others) in which CC is soluble can be employed and film forming solvents other than EA (e.g., other alkyl esters, ketones, among others) can be employed in making useful PDNI-H compound ink formulations.

OPV devices in this example have been fabricated and tested unencapsulated in air without any precautionary measures. Conventional device architecture [glass/ITO/PEDOT:PSS/PM6:Y6 active layer/(PDIN-H/CC or CN-PDIN-H/CC)/Ag] was used for device fabrication. ITO-patterned substrates were cleaned by sequentially ultrasonicating with detergent and deionized water, acetone, and isopropanol followed by UV/ozone cleaning for 30 min. PEDOT:PSS was spin coated at 4000 rpm for 60 seconds and then annealed at 140° C. for 20 min in air. PM6:Y6 photoactive layers were spin coated at 3500 rpm for 40 seconds and annealed at 110° C. for 10 min in air. PDIN-H/CC and CN-PDIN-H/CC CILs (ETLs) were either spin coated (from PrOH) or slot-die coated (from EA with added PrOH) on top of the photoactive layer. PDIN-H/CC and CN-PDIN-H/CC interlayers were spin coated at 6000 rpm for 40 seconds (unless otherwise noted). PDIN-H/CC and CN-PDIN-H/CC CILs interlayers were coated using a compact sheet coater from FOM Technologies equipped with a 13 mm wide slot-die head using a solution dispense rate (pump rate) of 50 μL/min and a substrate motion speed of 75 mm/min. PFN-Br control interlayers were spin coated from 0.5 mg/mL methanol solutions at 4000 rpm. All organic films were coated in air. A 100 nm Ag electrode was thermally evaporated under vacuum (1×10⁻⁵ Torr) to complete the device. The photoactive areas of the OPV devices were defined by a shadow mask to be 0.14 cm².

### OPV Device and Films Characterization

The current density-voltage (J-V) curves were measured by a Keithley 2420 source measure unit. The photocurrent was measured under AM 1.5 illumination at 100 mW/cm² (Newport 92251A-1000 Solar Simulator). The standard silicon solar cell (Newport 91150V) was used to calibrate light intensity. External quantum efficiency (EQE) was measured in a QEX7 Solar Cell Spectral Response/QE/IPCE Measurement System (PV Measurement, model QEX7, USA) with an optical lens to focus the light into an area about 0.04 cm², smaller than the cell. The silicon reference cell was used to calibrate the EQE measurement system in the wavelength range from 300 to 1100 nm. UV-Visible Spectroscopy (UV-Vis) measurements were recorded using an Agilent Technologies Cary 60 UV-Vis spectrometer at room temperature. AFM was acquired using a TT-2 AFM (AFM Workshop, USA) in the tapping mode and WSxM software with a 0.01-0.025 Ohm/cm Sb (n) doped Si probe with a reflective back side aluminum coating.

### REFERENCES

[1] C. Li, J. Zhou, J. Song, J. Xu, H. Zhang, X. Zhang, J. Guo, L. Zhu, D. Wei, G. Han, J. Min, Y. Zhang, Z. Xie, Y. Yi, H. Yan, F. Gao, F. Liu, Y. Sun, Nat. Energy 2021, 1.
[2] Yuanbao Lin, Y. Firdaus, F. H. Isikgor, M. I. Nugraha, E. Yengel, G. T. Harrison, R. Hallani, A. El Labban, H. Faber, C. Ma, X. Zheng, A. S. Subbiah, C. T. Howells, O. M. Bakr, I. McCulloch, S. De Wolf, L. Tsetseris, T. D. Anthopoulos, ACS Energy Lett. 2020, 5, 9, 2935-2964.
[3] L. Nian, W. Zhang, N. Zhu, L. Liu, Z. Xie, H. Wu, F. Würthner, Y. Ma, J. Am. Chem. Soc. 2015, 137, 6995.
[4] Z. A. Page, Y. Liu, V. V. Duzhko, T. P. Russell, T. Emrick, Science 2014, 346, 441.
[5] J. Yao, B. Qiu, Z.-G. Zhang, L. Xue, R. Wang, C. Zhang, S. Chen, Q. Zhou, C. Sun, C. Yang, M. Xiao, L. Meng, Y. Li, Nat. Commun. 2020, 11, 2726.
[6] R. Sorrentino, E. Kozma, S. Luzzati, R. Po, Energy Environ. Sci. 2021, 14, 180.
[7] M. E. Farahat, A. Laventure, M. A. Anderson, M. Mainville, F. Tintori, M. Leclerc, E. L. Ratcliff, G. C. Welch, ACS Appl. Mater. Interfaces 2020, 12, 43684.
[8] N. G. An, J. Y. Kim, D. Vak, Energy Environ. Sci. 2021, 14, 3438-3446.
[9] S. Strohm, F. Machui, S. Langner, P. Kubis, N. Gasparini, M. Salvador, I. McCulloch, H.-J. Egelhaaf, C. J. Brabec, Energy Environ. Sci. 2018, 11, 2225.
[10] Q. Kang, B. Yang, Y. Xu, B. Xu, J. Hou, Adv. Mater. 2018, 30, 1801718.
[11] R. Sun, Q. Wu, J. Guo, T. Wang, Y. Wu, B. Qiu, Z. Luo, W. Yang, Z. Hu, J. Guo, M. Shi, C. Yang, F. Huang, Y. Li, J. Min, Joule 2020, 4, 407.
[12] A. C. D. K. Dubey, M. Pahlevani, G. C. Welch, Adv. Mater. Technol. (June 2021) 2100264.
[13] Y. Bai, C. Zhao, S. Zhang, S. Zhang, R. Yu, J. Hou, Z. Tan, Y. Li, Sci. China Chem. 2020, 63, 957.
[14] Y. Lin, Y. Jin, S. Dong, W. Zheng, J. Yang, A. Liu, F. Liu, Y. Jiang, T. P. Russell, F. Zhang, F. Huang, L. Hou, Adv. Energy Mater. 2018, 8, 1701942.
[15] Q. Kang, L. Ye, B. Xu, C. An, S. J. Stuard, S. Zhang, H. Yao, H. Ade, J. Hou, Joule 2019, 3, 227.
[16] C. Huang, S. Barlow, S. R. Marder, J. Org. Chem. 2011, 76, 2386.
[17] Z.-G. Zhang, B. Qi, Z. Jin, D. Chi, Z. Qi, Y. Li, J. Wang, Energy Environ. Sci. 2014, 7, 1966.
[18] H.-L. Yip, A. K.-Y. Jen, Energy Environ. Sci. 2012, 5, 5994.
[19] M. Abd-Ellah, J. Cann, S. V. Dayneko, A. Laventure, E. Cieplechowicz, G. C. Welch, ACS Appl. Electron. Mater. 2019, 1, 1590.
[20] M. Sadeghianlemraski, C. R. Harding, G. C. Welch, H. Aziz, ACS Appl. Energy Mater. 2020, 3, 11655.
[21] C. R. Harding, J. Cann, A. Laventure, M. Sadeghianlemraski, M. Abd-Ellah, K. R. Rao, B. Sidney Gelfand, H. Aziz, L. Kaake, C. Risko, G. C. Welch, Mater. Horiz. 2020, 7, 2959.
[22] J. Huang, Z. Xu, Y. Yang, Adv. Funct. Mater. 2007, 17, 1966.
[23] J. Huang, G. Li, Y. Yang, Adv. Mater. 2008, 20, 415.
[24] H.-H. Liao, L.-M. Chen, Z. Xu, G. Li, Y. Yang, Appl. Phys. Lett. 2008, 92, 173303.
[25] Q. Guo, Q. Guo, Y. Geng, A. Tang, M. Zhang, M. Du, X. Sun, E. Zhou, Mater. Chem. Front. 2021, 5, 3257.
[26] M. Vespa, J. R. Cann, S. V. Dayneko, O. A. Melville, A. D. Hendsbee, Y. Zou, B. H. Lessard, G. C. Welch, Eur. J. Org. Chem. 2018, 2018, 4592.
[27] X. Wen, A. Nowak-Król, O. Nagler, F. Kraus, N. Zhu, N. Zheng, M. Müller, D. Schmidt, Z. Xie, F. Würthner, Angew. Chem. Int. Ed. 2019, 58, 13051.
[28] A. D. Hendsbee, J.-P. Sun, W. K. Law, H. Yan, I. G. Hill, D. M. Spasyuk, G. C. Welch, Chem. Mater. 2016, 28, 7098.
[29] Lai, T-H, Tsang, S-W., Manders, J. R., Chen, S., So, F., Properties of Interface Layers of Organic Photovoltaics, 2013, Materials Today 16(11): 424-432.
[30] Zhou, Y, et al. A Universal Method to Produce Low-Work Function Electrodes for Organic Electronics, 2012, Science, 336 (6079): 327-332.
[31] Martell, M.; Ocheje, M. U.; Gelfand, B. S.; Rondeau-Gagné, S.; Welch, G. C. Sidechain Engineering of N-Annulated Perylene Diimide Molecules. New J. Chem. 2021, 45 (45), 21001-21005.

1. A multi-layer Organic Photovoltaic (OPV) device comprising a top electrode, a bottom electrode, a photoactive layer and an electron transport layer (ETL), wherein the ETL is a film comprising an N-annulated perylene diimide (NPDI) compound having at least one pyrrole N—H bond and at least 1 equivalent of Cs₂CO₃ with respect to the number of pyrrole N—H bonds of the NPDI compound and the amount of the NPDI compound in the ETL layer.

2. The multi-layer device of claim 1, wherein the NPDI compound is a compound of Formula I: 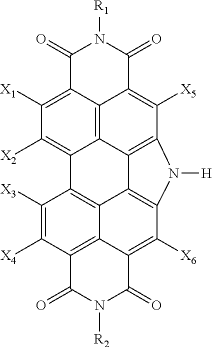
wherein:
R₁ and R₂ are independently a substituted or unsubstituted C₁ to C₁₈ linear or branched alkyl; and
X₁-X₆ are independently selected from H, a C₁-C₆ substituted or unsubstituted alkyl, a halogen, NO₂, or CN or X₂ and X₃ together form —S—S— and X₁, X₄, X₅ and X₆ are independently selected from H, a C₁-C₆ substituted or unsubstituted alkyl, a halogen, NO₂, or CN;
wherein optional substitution of alkyl groups is substitution with one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl, —NHR′ or —NR′R″, wherein R′ and R″ are independently H, an unsubstituted C₁ to C₆ alkyl or a C₁-C₃ halogen-substituted C₁-C₆ alkyl.

3. The multilayer device of claim 2, wherein the NPDI compound is a compound of Formula I, wherein X₁-X₆ are all hydrogens and R₁ and R₂ are independently branched alkyl groups having 5-11 carbon atoms.

4. The multilayer device of claim 2, wherein the NPDI compound is compound 1, compound 2 or compound 3.

5.-7. (canceled)

8. The multilayer device of claim 1, wherein the OPV device has conventional geometry wherein the ETL is positioned between the photoactive layer and the top electrode (cathode).

9. (canceled)

10. The multilayer device of claim 1, wherein the ETL contains from 1-5 equivalents of Cs₂CO₃ with respect to the amount of NPDI compound and the number of pyrrolic N—H bonds therein.

11.-30. (canceled)

31. The multilayer device of claim 1, wherein the photoactive layer is a bulk heterojunction layer.

32. The multilayer device of claim 1, further comprising a hole transport layer (HTL).

33. The multilayer device of claim 32, wherein the HTL is positioned between the photoactive layer and the bottom electrode.

34. The multilayer device of claim 1, wherein the top electrode is a metal electrode.

35. (canceled)

36. The multilayer device of claim 1, wherein the bottom electrode is glass/ITO, glass/reduced graphene oxide or glass/high conductivity PEDOT:PSS.

37.-38. (canceled)

39. A method for fabricating a multilayer device of claim 1, which comprises:
(a) deposition of a solution in a polar solvent comprising a N-annulated perylene diimide (NPDI) compound having at least one pyrrole N—H bond and at least 1 equivalent of Cs₂CO₃ with respect to the amount of NPDI compound and the number of pyrrolic bonds therein; and
(b) removal of the polar solvent to form the ETL.

40. The method of claim 39, wherein the solution is deposited by spin coating, spray coating, ink-jet printing, screen printing or slot die coating.

41. The method of claim 39, wherein the ETL is formed in air without humidity control.

42. The method of claim 39, wherein the ETL is formed by deposition of the solution on the photoactive layer.

43. The method of claim 39, wherein the solvent of the solution is a C1-C4 alcohol, ethyl acetate or a miscible mixture thereof.

44. The method of claim 39, wherein the solvent of the solution is a 1-propanol, ethanol or a mixture of ethyl acetate and 1-propanol or ethanol.

45. The method of claim 39, wherein the NPDI compound is a compound of Formula I: 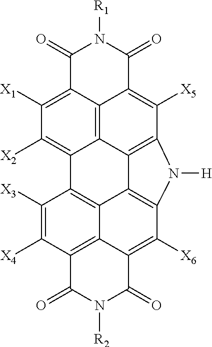
wherein:
R₁ and R₂ are independently a substituted or unsubstituted C₁ to C₁₃ linear or branched alkyl; and
X₁-X₆ are independently selected from H, a C₁-C₆ substituted or unsubstituted alkyl, a halogen, NO₂, or CN or X₂ and X₃ together form —S—S— and X₁, X₄, X₅ and X₆ are independently selected from H, a C₁-C₆ substituted or unsubstituted alkyl, a halogen, NO₂, or CN;
wherein optional substitution of alkyl groups is substitution with one or more halogens, —CN, —NO₂, —C(O)R′, —COOR′, —C(O)NH₂, —NHC(O)R′, —C(O)NR′R″, —CF₃, —SO₃H, —SO₂CF₃, —SO₂R′, —SO₂NR′R″, —OR′, —OC(O)R′, substituted or unsubstituted phenyl, substituted or unsubstituted benzyl, substituted or unsubstituted alkenyl, —NHR′ or —NR′R″, wherein R′ and R″ are independently H, an unsubstituted C₁ to C₆ alkyl or a C₁-C₃ halogen-substituted C₁-C₆ alkyl.

46. The method of claim 45, wherein the solution contains at least one equivalent of Cs₂CO₃ with respect to the amount of NPDI compound therein.

47. The method of claim 45, wherein the NPDI compound is compound 1, compound 2 or compound 3.
